(19) United States
(12) Patent Application Publication
(10) Pub. No.: US 2022/0169430 A1
(43) Pub. Date: Jun. 2, 2022

(54) BIODEGRADABLE AND COMPOSTABLE VESSELS, SUCH AS COFFEE PODS, COATED WITH PECVD COATINGS OR LAYERS

(71) Applicant: SIO2 MEDICAL PRODUCTS, INC., Auburn, AL (US)

(72) Inventors: Ahmad Taha, Auburn, AL (US); Adam Breeland, Notasulga, AL (US)

(21) Appl. No.: 17/594,178

(22) PCT Filed: Apr. 3, 2020
(86) PCT No.: PCT/US2020/026756

§ 371 Date: Oct. 5, 2021

Related U.S. Application Data
(60) Provisional application No. 62/860,036, filed on Jun. 11, 2019.
(60) Provisional application No. 62/858,625, filed on Jun. 7, 2019.
(60) Provisional application No. 62/830,299, filed on Apr. 5, 2019.

(51) Int. Cl. B65D 65/46; C08J 7/04; B65D 85/804; B65D 65/42; C23C 16/50; C23C 16/40

(52) U.S. Cl. CPC B65D 65/466; C08J 7/0423; B65D 85/8046; C08J 2393/02; C23C 16/50; C23C 16/401; C08J 2397/00; B65D 65/42

(57) ABSTRACT

Embodiments of the present disclosure are directed to a vessel comprising a wall at least partially made of a compostable or biodegradable material, having an interior surface enclosing a lumen and an exterior surface; and a PECVD coating set on the interior surface, the exterior surface, or both. The PECVD coating set comprises a barrier coating or layer of SiOx, in which x is from about 1.5 to about 2.9 as measured by XPS. The PECVD coating set optionally further comprises a tie coating or layer comprising SiOxCy, in which x is from about 0.5 to about 2.4 and y is from about 0.6 to about 3 as measured by X-ray photoelectron spectroscopy (XPS); a pH protective coating or layer comprising SiOxCy, in which x is from about 0.5 to about 2.4 and y is from about 0.6 to about 3 as measured by XPS; or both. The vessel may also include a lacquer coating between the surface of the wall and the PECVD coating set. In some embodiments, the vessel may be a single use coffee or tea pod.

This application claims priority to (i) U.S. Provisional Patent Application No. 62/830,299, filed Apr. 5, 2019, (ii) U.S. Provisional Patent Application No. 62/858,625, filed Jun. 7, 2019, and (iii) U.S. Provisional Patent Application No. 62/860,036, filed Jun. 11, 2019, each of which is incorporated by reference herein in its entirety. All other references cited in this document are also incorporated by reference in their entirety.

### FIELD OF THE INVENTION

The present invention relates to the technical field of a PECVD coated vessel made of compostable or biodegradable material with improved gas and/or water vapor bather properties. The invention also relates to a PECVD coated vessel made of compostable or biodegradable material with an improved leachable profile from the compostable or biodegradable material.

The present invention further relates to a single-use coffee pod having a surface coated with a PECVD coating set to provide improved gas and/or water vapour barrier properties, improved leachable profile, reduced flavour scalping, reduced changes in headspace gas, and/or longer shelf-life. The single-use coffee pod may be made of a compostable or biodegradable material and may remain compostable or biodegradable after application of the PECVD coating set.

The present invention further relates to the methods for preparing the coated vessels. The present invention also relates to the use of the coated vessels.

### BACKGROUND OF THE INVENTION

One important consideration in manufacturing food, beverage, or pharmaceutical containers is that the contents usually must have a substantial shelf life. In many cases, the contents are sensitive to air, oxygen, moisture or other environmental factors. During this shelf life, it is important to isolate the contents filling the containers from atmospheric gases such as oxygen and moisture. It is also important to block the leachables from the container wall material. Therefore the barrier properties of the vessel wall are crucial in these applications.

Glass provides good barrier properties. However it is prone to breakage or contents degradation during manufacture, filling operations, shipping and use, which means that glass particulates may enter the contents. The presence of glass particles has led to many FDA Warning Letters and to product recalls. As a result, in pharmaceutical and food industries, some companies have turned to plastic packages, which provide greater dimensional tolerance and less breakage than glass.

However both glass and plastic cause environmental problems. They are neither degradable in nature nor digestible. Popular plastic packaging material in food and beverage applications, such as polyvinyl chloride (PVC), never truly decomposes. It can take up to 1,000 years for polyethylene to degrade in nature. Other plastics can take various lengths of time to degrade in nature, averaging at about 450 years.

Traditional plastics last almost forever, causing pollution and poisoning or injuring animals. More and more industries turn to compostable or biodegradable material for packaging needs. Many compostable or biodegradable materials are derived from renewable raw materials like starch such as corn, potato, or tapioca; cellulose; soy protein; lactic acid; wood, bamboo, or other wood-like fiber products; or sun flower seed shells/husks. US 2016/0108187 A1 and U.S. Pat. No. 10,173,353 B2 describe compostable or biodegradable materials based on sunflower seed shells or sunflower seed hulls, for example.

However, like traditional plastics, the use of compostable or biodegradable materials in the pharmaceutical and food/beverage industries has some drawbacks. First, most compostable or biodegradable materials have poor barrier properties. The materials allow small molecule gases, such as oxygen and water molecules, to permeate into (or out of) the article. In many cases, the content in the packaging is oxygen and moisture sensitive. Another issue is leachables migrating from the packaging material into the drugs or food/beverage contained in the packaging. For coffee and tea pods (also referred to as capsules) or other brewing cups, for example, barrier properties are very important because coffee and tea are very sensitive to oxygen, moisture and leachables during storage, which can cause flavour to change.

For traditional plastic packaging, such as coffee K-CUPS®, NESPRESSO® coffee pods, and the like, as well as bottles and single-serve containers for other consumable items such as catsup, the problem of permeability has been addressed by using a multi-layer plastic material. Similarly, in order to address the barrier property issue, compostable or biodegradable multiple layer materials have been developed, as described for example in US 2007/0042207 A1.

However, packaging made of multilayer compostable or biodegradable material is difficult to mold and expensive to manufacture. In addition, using multilayer compostable or biodegradable materials does not address the leachable problem.

### SUMMARY OF INVENTION

The current invention addresses the permeability and leachability problems of pharmaceutical or food/beverage packaging by providing one or more thin plasma-enhanced chemical vapour deposition (PECVD) coatings or layers on a wall surface of a vessel (i.e. packaging) made of compostable or biodegradable material.

An aspect of the invention is a vessel having a wall made of a compostable or biodegradable material. The wall has an interior surface enclosing at least a portion of a lumen and an exterior surface; and a PECVD coating set on the interior surface or the exterior surface or both. The PECVD coating set comprises at least a barrier coating or layer of SiOx, in which x is from about 1.5 to about 2.9 as measured by XPS. Optionally the lumen is closed by a closure.

Optionally, the PECVD coating set further comprises a tie coating or layer comprising SiOxCyHz (or its equivalent SiOxCy), in which x is from about 0.5 to about 2.4 as measured by X-ray photoelectron spectroscopy (XPS), y is from about 0.6 to about 3 as measured by XPS, and z (if defined) is from about 2 to about 9 as measured by at least one of Rutherford backscattering spectrometry (RBS) or hydrogen forward scattering (HFS); wherein the SiOx barrier coating or layer is on top of the tie coating or layer, i.e. where the tie coating or layer is positioned between the vessel wall and the SiOx barrier coating or layer.

Optionally, the PECVD coating set further comprises a pH protective coating or layer of SiOxCyHz (or its equivalent SiOxCy), in which x is from about 0.5 to about 2.4 as measured by XPS, y is from about 0.6 to about 3 as measured by XPS, and z (if defined) is from about 2 to about 9 as measured by at least one of RBS or HFS; wherein the pH protective coating or layer is on top of the SiOx barrier coating or layer, i.e. between the barrier coating or layer and the lumen when the coating set is on the interior surface of the vessel or between the barrier coating or layer and the exterior of the vessel when the coating set is on the exterior surface of the vessel wall.

Optionally, a wall surface treatment, for example a lacquer coating or layer, is applied directly on the wall under the PECVD coating set.

Optionally, the wall is made of compostable or biodegradable material with a single layer structure.

Optionally, the vessel is a food container, a coffee or tea brewing cup, a single use coffee or tea pod (capsule), a tube, a bottle, a jar, a food package, a blister package, a flexible package, such as a pouch, or the like.

Other aspects of the invention will be apparent from the description and claims following.

### Definitions

In the context of the present invention, the following definitions and abbreviations are used:

“Biodegradable” in the context of the present invention refers to a material that undergoes degradation (is broken down) by the action of naturally occurring microorganisms such as bacteria, fungi, and algae. This includes materials that satisfy the ASTM definition of “biodegradable plastic” set forth by the American Society for Testing and Materials (ASTM) in ASTM D 6400 (“a degradable plastic in which the degradation results from the action of naturally occurring microorganisms such as bacteria, fungi, and algae”) and/or the International Organization for Standardization (ISO) set forth in EN ISO 472:2001 (“degradable plastic in which degradation results in lower molecular weight fragments produced by the action of naturally occurring microorganisms such as bacteria, fungi and algae”).

“Compostable” in the context of the present invention refers to a material that undergoes degradation (is broken down) by biological processes during composting, which takes place in the presence of oxygen and under controlled conditions by the action of micro- and macroorganisms to produce a humus-like substance called compost. This includes materials that satisfy the ASTM definition of “compostable plastic” set forth by the American Society for Testing and Materials (ASTM) in ASTM D 6400 (“a plastic that undergoes degradation by biological processes during composting to yield carbon dioxide, water, inorganic compounds, and biomass at a rate consistent with other known compostable materials and leaves no visually distinguishable or toxic residues”), the International Organization for Standardization (ISO) set forth in SIO/DIS 17088 (same). This includes materials that satisfy standards for home compostability and/or for commercial/industrial compostability, such as may be set by EN 13432, ASTM D 6400, AS 4736, AS 5810, and the like. Note that “compostable” is a subset of “biodegradable,” i.e. compostable materials are biodegradable but not all biodegradable materials are necessarily compostable.

European Standard EN13432 states (i) that a material is deemed to be compostable by measuring the actual metabolic conversion of the material into carbon dioxide; (ii) a material is characterized as biodegradable if in less than six months, the material has biodegraded by 90%; (iii) the material also has to pass a composting test (EN 14045) where the material is sieved with a 2.0-mm sieve after 3 months, the residue can be no higher than 2 mm. This must be less than 10% of the material's original mass; (iv) there must be an absence of negative effects on the composting process and low levels of heavy metals; and (v) the material has to pass the plant growth test (OECD 208, modified) where the test material must be the same as the control compost. All of these various requirements must be simultaneously met to be defined as compostable and meet the European Standard EN 13432. Notably, EN 13432 provides reduced restrictions for additives that do not exceed 1 wt. % of the compostable material. According to EN 13432, “for each additive which is present in a product that does not exceed 1% by mass, only a designation of suitability to a composting process by way of Material Safety Data Sheet (MSDS) and quantitative heavy metal analysis is required.”

According to section 6.2 of the ASTM D6400, Standard Specification for Compostable Plastics, plastic products are deemed to have disintegrated during composting if after twelve weeks in a controlled composting test, no more than 10% of its original dry weight remains after sieving on a 2.0-mm sieve. The compositing conditions are generated in a laboratory thermophilic by performing Test Method D5338 without CO2 trapping component, or ISO 16929.

RF is radio frequency.

The term “at least” in the context of the present invention means “equal or more” than the integer following the term. The word “comprising” does not exclude other elements or steps, and the indefinite article “a” or “an” does not exclude a plurality unless indicated otherwise. Whenever a parameter range is indicated, it is intended to disclose the parameter values given as limits of the range and all values of the parameter falling within said range.

“First” and “second” or similar references to, for example, deposits of lubricant, processing stations or processing devices refer to the minimum number of deposits, processing stations or devices that are present, but do not necessarily represent the order or total number of deposits, processing stations and devices or require additional deposits, processing stations and devices beyond the stated number. These terms do not limit the number of processing stations or the particular processing carried out at the respective stations. For example, a “first” deposit in the context of this specification can be either the only deposit or any one of plural deposits, without limitation. In other words, recitation of a “first” deposit allows but does not require an embodiment that also has a second or further deposit.

For purposes of the present invention, an “organosilicon precursor” is a compound having at least one of the linkages:

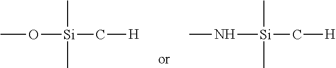

which is a tetravalent silicon atom connected to an oxygen or nitrogen atom and an organic carbon atom (an organic carbon atom being a carbon atom bonded to at least one hydrogen atom). A volatile organosilicon precursor, defined as such a precursor that can be supplied as a vapor in a PECVD apparatus, is an optional organosilicon precursor. Optionally, the organosilicon precursor is selected from the group consisting of a linear siloxane, a monocyclic siloxane, a polycyclic siloxane, a polysilsesquioxane, an alkyl trimethoxysilane, a linear silazane, a monocyclic silazane, a polycyclic silazane, a polysilsesquiazane, and a combination of any two or more of these precursors.

The feed amounts of PECVD precursors, gaseous reactant or process gases, and carrier gas are sometimes expressed in “standard volumes” in the specification and claims. The standard volume of a charge or other fixed amount of gas is the volume the fixed amount of the gas would occupy at a standard temperature and pressure (without regard to the actual temperature and pressure of delivery). Standard volumes can be measured using different units of volume, and still be within the scope of the present disclosure and claims. For example, the same fixed amount of gas could be expressed as the number of standard cubic centimeters, the number of standard cubic meters, or the number of standard cubic feet. Standard volumes can also be defined using different standard temperatures and pressures, and still be within the scope of the present disclosure and claims. For example, the standard temperature might be 0° C. and the standard pressure might be 760 Torr (as is conventional), or the standard temperature might be 20° C. and the standard pressure might be 1 Torr. But whatever standard is used in a given case, when comparing relative amounts of two or more different gases without specifying particular parameters, the same units of volume, standard temperature, and standard pressure are to be used relative to each gas, unless otherwise indicated.

The corresponding feed rates of PECVD precursors, gaseous reactant or process gases, and carrier gas are expressed in standard volumes per unit of time in the specification. For example, in the working examples the flow rates are expressed as standard cubic centimeters per minute, abbreviated as sccm. As with the other parameters, other units of time can be used, such as seconds or hours, but consistent parameters are to be used when comparing the flow rates of two or more gases, unless otherwise indicated.

A “vessel” in the context of the present invention can be any type of vessel with at least one opening and a wall defining an inner or interior surface. The substrate can be the wall of a vessel having a lumen. The substrate surface can be part or all of the inner or interior surface of a vessel having at least one opening and an inner or interior surface. Though the invention is not limited to pharmaceutical packages or other vessels of a particular volume, pharmaceutical packages or other vessels are contemplated in which the lumen has a void volume of from 0.5 to 50 mL, optionally from 1 to 10 mL, optionally from 0.5 to 5 mL, optionally from 1 to 3 mL. Some examples of a pharmaceutical package include, but are not limited to, a vial, a plastic-coated vial, a syringe, a plastic coated syringe, a blister pack, an ampoule, a plastic coated ampoule, a cartridge, a bottle, a plastic coated bottle, a pouch, a pump, a sprayer, a stopper, a needle, a plunger, a cap, a tube, a stent, a catheter or an implant. Similarly, though the invention is not limited to food or beverage containers or other vessels of a particular shape or volume, food containers such as coffee or tea brewing cups, single use coffee or tea pods (capsules), bottles, jars, flexible food packages (e.g. pouches), and other food containers are contemplated.

The term “at least” in the context of the present invention means “equal or more” than the integer following the term. Thus, a vessel in the context of the present invention has one or more openings. One or two openings, like the openings of a sample tube (one opening) or a syringe barrel (two openings) are preferred. If the vessel has two openings, they can be of same or different size. If there is more than one opening, one opening can be used for the gas inlet for a PECVD coating set method according to the present invention, while the other openings are either capped or open.

A vessel can be of any shape, a vessel having a substantially cylindrical wall adjacent to at least one of its open ends being preferred. Generally, the interior wall of the vessel is cylindrically shaped, like, for example in a coffee or tea pod.

These values of w, x, y, and z are applicable to the empirical composition SiwOxCyHz throughout this specification. The values of w, x, y, and z used throughout this specification should be understood as ratios or an empirical formula (for example for a coating or layer), rather than as a limit on the number or type of atoms in a molecule. For example, octamethylcyclotetrasiloxane, which has the molecular composition Si4O4C8H24, can be described by the following empirical formula, arrived at by dividing each of w, x, y, and z in the molecular formula by 4, the largest common factor: Si1O1C2H6. The values of w, x, y, and z are also not limited to integers. For example, (acyclic) octamethyltrisiloxane, molecular composition Si3O2C8H24, is reducible to Si1O0.67C2.67H8. Also, although SiOxCyHz is described as equivalent to SiOxCy, it is not necessary to show the presence of hydrogen in any proportion to show the presence of SiOxCy.

BIF is defined as the ratio of the gas transmission rate through the uncoated substrate to the gas transmission rate through the coated substrate. For example, a BIF regarding water vapor transmission of a coated vessel is the ratio of WVTR (uncoated)/WVTR (coated).

“Water vapor barrier coating or layer (WVBC)” in the context of the current specification means that the coating or layer lowers the water vapor transmission rate (WVTR) of the coated substrate compared to the uncoated substrate.

“Water vapor barrier coating or layer (WVBC)” is sometimes also referred to “water vapor barrier coating or layer (WBC)”. WVBC is exchangeable with WBC in this specification.

“Wetting tension” is a specific measure for the hydrophobicity or hydrophilicity of a surface. An optional wetting tension measurement method in the context of the present invention is ASTM D 2578 or a modification of the method described in ASTM D 2578. This method uses standard wetting tension solutions (called dyne solutions) to determine the solution that comes nearest to wetting a plastic film surface for exactly two seconds. This is the film's wetting tension. The procedure utilized is varied herein from ASTM D 2578 in that the substrates are not flat plastic films, but are tubes made according to the Protocol for Forming PET Tube and (except for controls) coated according to the Protocol for coating Tube Interior with Hydrophobic Coating or Layer (see Example 9 of EP2251671A2).

The atomic ratio can be determined by XPS. Taking into account the H atoms, which are not measured by XPS, the coating or layer may thus in one aspect have the formula SiwOxCyHz (or its equivalent SiOxCy), for example where w is 1, x is from about 0.5 to about 2.4, y is from about 0.6 to about 3, and z is from about 2 to about 9. Typically, such coating or layer would hence contain 36% to 41% carbon normalized to 100% carbon plus oxygen plus silicon.

A “trilayer coating or layer” refers to a PECVD coating set comprising a tie layer, a SiOx barrier coating or layer and a pH protective layer.

The word “comprising” does not exclude other elements or steps.

The indefinite article “a” or “an” does not exclude a plurality.

In pharmaceutical or food packaging industries, the “headspace” refers to the internal space of a package that is not occupied by the product. The atmosphere in this space is called the headspace gas. Headspace (gas) analysis is the measurement of this headspace gas, e.g. the components of the gas. Headspace gas analysis is important for the quality control process for the food, beverage and pharmaceutical industries.

A gas chromatography (GC) or gas liquid chromatography (GLC) method is frequently used to perform this type of headspace analysis.

For example, packaged coffee generates aroma into the headspace. Headspace analysis is important to monitor and maintain the quality, e.g. the flavor, during storage.

Flavor scalping is used to describe the flavor change of the content inside a packaging caused by either its volatile flavors being absorbed or adsorbed by the packaging material or the content absorbing undesirable flavors from its packaging material. A classic example is the absorption or adsorption of the packaging plastic flavors when food or drinks are stored in plastic containers for an extended period.

Leachables from the container materials, e.g. the plastics, the biodegradable/compostable wall material, can negatively affect the quality of the coffee.

In this invention, the PECVD coatings can block leachables of the container wall material from entering into the content or headspace. In addition, the PECVD coatings can also prevent flavor scalping.

### BRIEF DESCRIPTION OF DRAWING FIGURES

FIG. 1 is a schematic sectional view of a vessel having a vessel wall coated with a PECVD coating set.

FIG. 2 is a detail view of FIG. 1 showing an option according to FIG. 1: interior and exterior coatings on the wall 214.

FIG. 3 is a detail view similar to FIG. 2 showing another option according to FIG. 1: interior coatings only on the wall 214.

FIG. 4 is a perspective view of coffee pods which optionally can be coated according to FIG. 1.

FIG. 5 is a perspective view of single-use catsup containers which optionally can be coated according to FIG. 1.

FIG. 6 is a perspective schematic view of apparatus useful for PECVD coating the vessels of FIGS. 1-5.

The following reference characters are used in this description.

| | |
|---|---|
| 9 | PECVD coater |
| 10 | Treatment volume |
| 11 | Reaction chamber wall (optional) |
| 12 | Fluid source |
| 13 | Fluid inlet |
| 14 | Vessel, e.g. pod, holder |
| 15 | Plasma zone |
| 16 | Front surface (of 14) |
| 17 | Treatment gas |
| 18 | Plasma energy source |
| 19 | Lid (optional) |
| 20 | Plasma (boundary) |
| 21 | Substrate support (optional) |
| 22 | Vacuum source (optional) |
| 23 | Applicator |
| 24 | Remote conversion plasma region |
| 28 | Exterior surface (of 32) |
| 30 | Interior surface (of 32) |
| 32 | Pod/Capsule |
| 210 | Vessel |
| 212 | Lumen |
| 214 | Wall |
| 216 | Outer surface (of 214) |
| 220 | Trilayer |
| 224 | Lacquer |
| 226 | Lid |
| 278 | Inner surface (of 214) |
| 285 | PECVD coating set (inner) |
| 286 | pH protective coating or layer |
| 288 | Barrier coating or layer |
| 289 | Tie coating or layer |
| 301 | PECVD coating set (outer) |

### DETAILED DESCRIPTION

The present invention will now be described more fully, with reference to the accompanying drawings, in which several embodiments are shown. This invention can, however, be embodied in many different forms and should not be construed as limited to the embodiments set forth here. Rather, these embodiments are examples of the invention, which has the full scope indicated by the language of the claims. Like numbers refer to like or corresponding elements throughout. The following disclosure relates to all embodiments unless specifically limited to a certain embodiment. The specification and drawings of U.S. Pat. No. 7,985,188, PCT International Application No. US/2016/047622, PCT International Application No. US 2014/023813, U.S. Pat. No. 9,554,968, PCT International Application No. US 2017/026575, and WO2017/087032 are incorporated herein by reference in their entirety. The incorporated patents and applications describe apparatus, vessels, precursors, coatings or layers and methods (in particular coating methods and test methods for examining the coatings or layers) which can generally be used in performing the present invention, in some cases as modified herein.

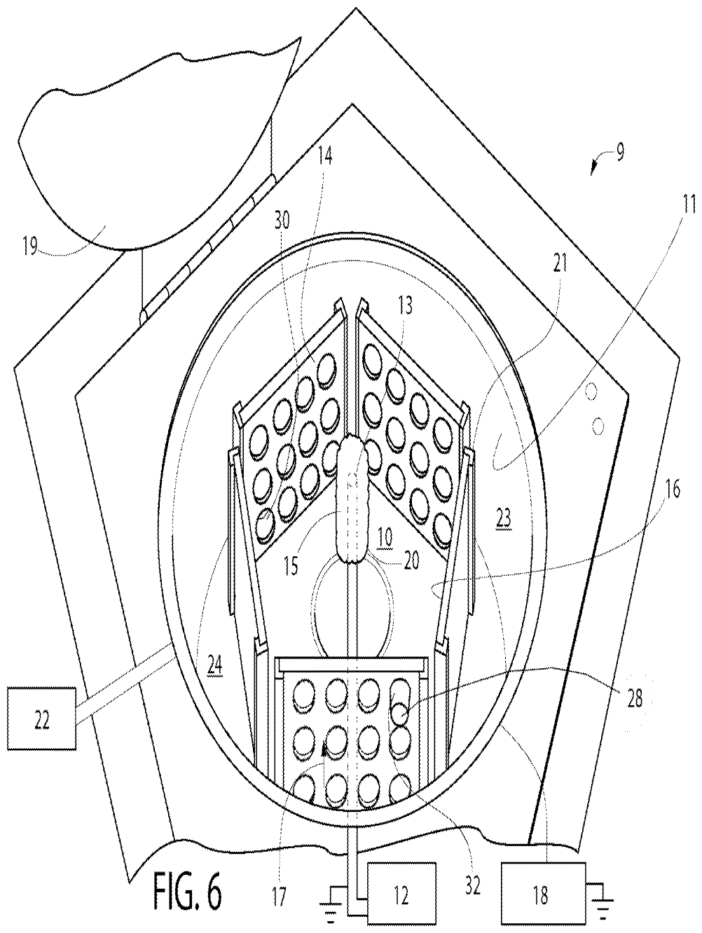

Many different types of apparatus are known to the skilled person for carrying out PECVD. The present disclosure is not limited to any particular apparatus or method, except as otherwise stated expressly. FIG. 6 illustrates one such PECVD coater 9 that can be used, for example to apply a PECVD coating, layer, or treatment to the inside and/or outside surfaces of a plurality of vessels 32. The process used to treat the vessels in FIG. 6 uses a radio-frequency (RF) plasma system. The system has a gas delivery input, a vacuum pump and RF power supply with matching network. The vessels are shown oriented with the interior surfaces facing toward the plasma and the exterior surfaces facing away from and shielded from the plasma.

FIG. 6 shows a plasma PECVD coater 9 comprising a treatment volume 10 defined and enclosed by a reaction chamber wall 11 having a fluid source 12 (in this instance, a tubular fluid inlet 13 projecting axially into the treatment volume 10, however other fluid sources are contemplated, e.g., “shower head” type fluid sources). The reaction chamber wall 11 in this embodiment was provided with a removable lid 19 that is openable to allow vessels to be inserted or removed, and sealable to contain the process and, optionally, evacuate the treatment volume. In one embodiment, the fluid source 12 may be made of metallic material, electrically grounded, and also function as an applicator, in the form of an inner electrode. As is known, the plasma optionally can also be generated without an inner electrode.

Feed gases were fed into the treatment volume 10. The plasma reaction chamber comprised an optional feature of a vacuum source 22 for at least partially evacuating the treatment volume 10. As illustrated, the plasma reaction chamber wall 11 also functioned as an applicator 23 in the form of an outer applicator or electrode surrounding at least a portion of the plasma reaction chamber. A plasma energy source 18, in this instance a radio frequency (RF) source, was coupled to applicators 23 defined by the reaction chamber wall 11 and the fluid source 12 to provide power that excited the gases to form plasma. The plasma zone 15 formed a visible glow discharge that was limited by the plasma boundary 20 in close proximity to the fluid source 12. The afterglow region also known as a remote conversion plasma region 24 is the region radially or axially outside the boundary 20 of the visible glow discharge and extending beyond the substrates treated.

Coffee pods or other vessels 32 having exterior surfaces 28 and interior surfaces 30 may be oriented such that when placed in wells on the front surfaces 16 of the pod holders 14, the surfaces on which treatment is desired (e.g. the interior surfaces 30 in the illustrated embodiment) face toward the fluid source 12 and the opposite surfaces (e.g. the exterior surfaces 28 in the illustrated embodiment) face away from the fluid source 12. The exterior surfaces 28 of the vessels 32 may be shielded by their own interior surfaces 30 to block the exterior surfaces 28 from being in the direct “line of sight” of the fluid source 12. In this manner, the process may rely on remote conversion plasma (as opposed to direct plasma) to treat the exterior surfaces 28 of the vessels 32. In other embodiments, the exterior surfaces 28 may be surrounded by portions of the pod holders 14 or some other external element, such that they are fully or substantially fully shielded from the plasma (including the remote plasma) and remain uncoated.

In yet other embodiments, the pod holders 14 may be reversed, such that the front surfaces 16 of the pod holders 14, and thus the wells, are directed away from the fluid source 12, in which case the surfaces on which treatment is desired (e.g. the interior surfaces 30) may be coated by remote plasma. In such an embodiment, the exterior surfaces 28 may be shielded by a portion of pod holder 14 or another external element, e.g. as described above, and remain uncoated. Or the exterior surfaces 28 may be exposed to the direct plasma.

Although the above embodiments are described in terms of the interior surfaces 30 being the surfaces on which treatment is desired, it should be recognized in other embodiments the exterior surfaces 28 of the vessels 32 may be the surfaces on which treatment is desired. In yet other embodiments, treatment may be desired on both the interior surfaces 30 and exterior surfaces 28 of vessels 32, in which case the vessel holders 14 may optionally be rotated during the PECVD coating process (e.g. automatically during the deposition of each layer or manually at one or more points in between the application of layers or coating sets).

One aspect of the invention is a vessel having a wall made of a compostable or biodegradable material. The wall has an interior surface enclosing at least a portion of a lumen and an exterior surface; and a plasma-enhanced chemical vapor deposition (PECVD) coating set on the interior surface or the exterior surface or both. The PECVD coating set comprises at least a barrier coating or layer of SiOx, in which x is from about 1.5 to about 2.9 as measured by XPS. Optionally the lumen is closed by a closure.

Optionally, the PECVD coating set further comprises a tie coating or layer on the wall interior surface comprising SiOxCyHz (or the equivalent SiOxCy), in which x is from about 0.5 to about 2.4 as measured by X-ray photoelectron spectroscopy (XPS), y is from about 0.6 to about 3 as measured by XPS, and z (if defined) is from about 2 to about 9 as measured by at least one of Rutherford backscattering spectrometry (RBS) or hydrogen forward scattering (HFS); and the SiOx barrier coating or layer is on top of the tie coating or layer.

Optionally, the PECVD coating set further comprises a pH protective coating or layer of SiOxCyHz (or the equivalent SiOxCy), in which x is from about 0.5 to about 2.4 as measured by XPS, y is from about 0.6 to about 3 as measured by XPS, and z (if defined) is from about 2 to about 9 as measured by at least one of RBS or HFS, positioned between the barrier coating or layer and the lumen.

Optionally, a surface treatment coating or layer, e.g. a lacquer coating or layer, is applied directly on the biodegradable wall under the PECVD coating set. Sometimes, a PECVD coating or layer directly applied on the biodegradable/compostable wall may not provide the optimal barrier properties. For example, when the PECVD coatings or layers applied directly on the vessel wall made of sunflower shells/hulls (available, for example, from The Golden Compound GmbH, Ladbergen Germany, as Golden Compound Green™), the optimal barrier property was not obtained. Without being bound by theory, it is thought that this is likely due to the surface roughness of the wall, which is common in biodegradable and compostable materials. It may also be due in part to the oil from the natural biodegradable/compostable material, preventing the PECVD coating or layer adhering to the wall. In order to address this issue, the surface of the wall is treated to increase the smoothness of the surface, e.g. a lacquer or other coating is applied directly on the biodegradable/compostable wall, followed by a PECVD coating or layer applied on top of the surface coating. The surface treatment can be applied by brushing, dipping, spraying, etc.

Optionally, the surface treatment (e.g. lacquer) and PECVD coating sets are applied on the interior surface of the wall or the exterior surface of the wall or both.

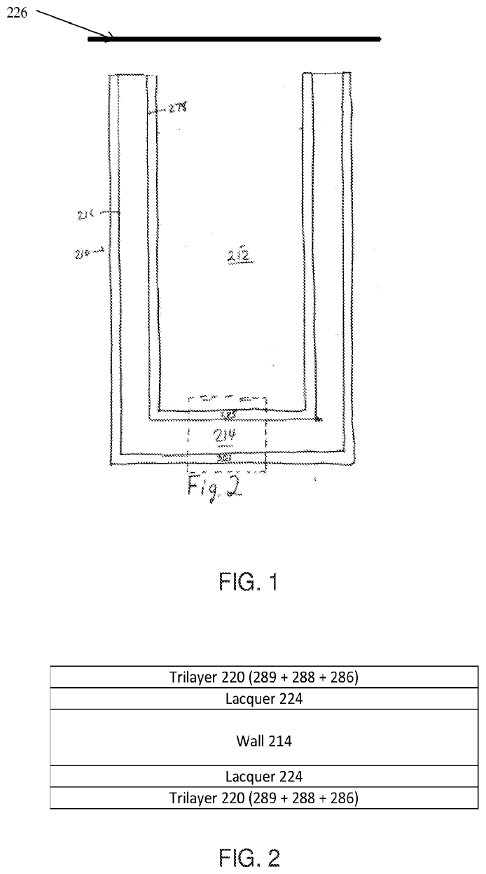

An aspect of the invention, illustrated most broadly by FIG. 1, is a vessel 210 including a wall 214 enclosing a lumen 212 and supporting at least one vessel coating set 285 or 301, optionally both. The vessel may be, for example, a food container, a coffee cup, a single use coffee pod, optionally a vial, a tube, a bottle, a jar, food package, a blister package, or a flexible package. The vessel optionally has a lid 226.

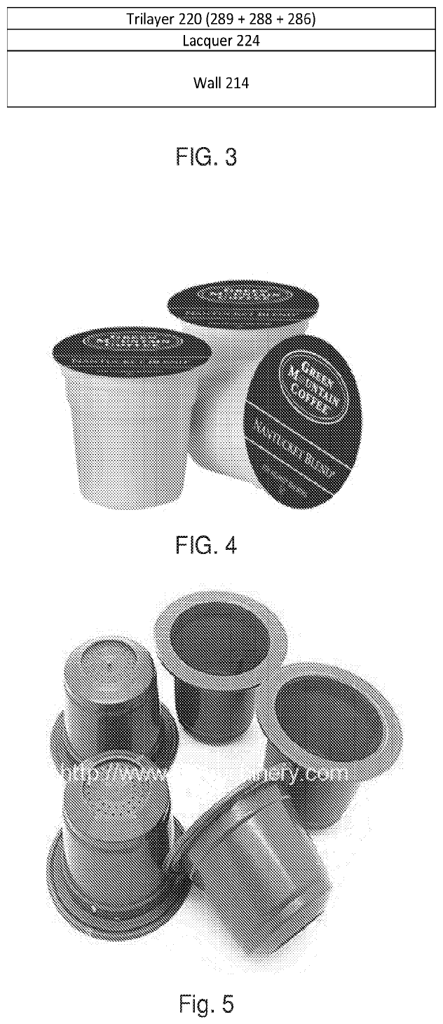

Optionally, as shown in FIGS. 1-3, the vessel 210 has an inner surface treatment (e.g. lacquer) coating or layer 224 applied to the inner surface 278 of the wall 214 and an inner PECVD coating set 285 optionally applied to the inner lacquer coating or layer 224. As another option, as shown in FIGS. 1 and 2 only, the vessel 210 has an outer surface treatment (e.g. lacquer) coating or layer 224 applied to the outer surface 216 of the wall 214 and an outer PECVD coating set such as trilayer 220 optionally applied to the outer lacquer coating or layer 224. As still another option, as shown in FIGS. 1 and 2 only, the vessel has inner and outer surface treatment (e.g. lacquer) coatings or layers 288 applied to the inner and outer surfaces 278 and 216 of the wall 214 and inner and outer PECVD coating sets such as trilayer 220 optionally applied to the inner and outer lacquer coatings or layers 288.

A PECVD coating set optionally comprises at least one tie coating or layer on the lacquer coating or layer 224, if used, does include at least one barrier coating or layer 288 either directly on the lacquer coating or layer 224 or on the tie coating or layer, and optionally further comprises at least one pH protective coating or layer 286 on the barrier coating or layer. This option for the vessel coating set of FIGS. 1-3 is sometimes known as a “trilayer coating” in which the barrier coating or layer 288 of SiOx is protected against contents having a pH otherwise high enough to remove it by being sandwiched between the pH protective coating or layer 286 and the tie coating or layer, each an organic layer of SiOxCy as defined in this specification. A specific example of this trilayer coating is provided in this specification. The contemplated thicknesses of the respective layers in nm (preferred ranges in parentheses) are given in the Trilayer Thickness Table. The total PECVD coating set can be less than 500 nm thick, alternatively less than 400 nm thick, alternatively less than 300 nm thick, alternatively less than 200 nm thick, alternatively less than 100 nm thick, alternatively less than 90 nm, alternatively less than 80 nm. This is important for manufacturing biodegradable and/or compostable vessels, such as coffee cups/pods, as explained in detail herein.

Trilayer Thickness Table

| Adhesion | Barrier | Protection |
|---|---|---|
| 5-100 | 20-200 | 50-500 |
| (5-20) | (20-30) | (100-200) |

Optionally the coatings or layers are on the interior surface of the wall. Optionally, the coatings or layers are on both of the interior surface and the exterior surface of the wall. Optionally, the coatings or layers are on both of the interior surface and the exterior surface of the wall.

Optionally in any embodiment, the respective coatings and layers can be variously ordered.

Vessels

The vessel can be embodied in many different forms and should not be construed as limited to the embodiments set forth here. Rather, these embodiments are examples of the invention, which has the full scope indicated by the language of the claims.

Optionally in any embodiment, the vessel 210 can be, for example, a food container, a coffee cup, a single use coffee pod, a vial, a tube, a bottle, a jar, food package, a blister package, a flexible package or a microplate.

Optionally, in any embodiment, the vessel may be made of a compostable of biodegradable material.

The compostable or biodegradable material may be derived from renewable resources. For example, in any embodiment, the compostable or biodegradable material may be derived from renewable raw materials like starch such as corn, potato, tapioca; cellulose; soy protein; lactic acid; lignin; wood, bamboo, or other wood-like fiber product; or sun flower seed shells/husks. Biodegradable polymers from renewable resources include polylactide (also known as polylactic acid (PLA)), polyhydroxyalkanoates (PHAs) such as poly(3-hydroxybutyrate) (PHB) and PHB copolymers, poly(butylene succinate) (PBS), thermoplastic starch (TPS), starch blends, cellulose and cellulose esters, chitosan, and proteins. These are often referred to as bioplastics, biopolymers, or bio-based plastics or polymers. In some embodiments, the compostable or biodegradable material may comprise one or more of these renewable resource-derived biodegradable polymers.

The compostable or biodegradable material may also be derived from petroleum sources. Such materials include aliphatic polyesters and copolyesters such as poly(butylene succinate) (PBS), poly(butylene succinate adipate) (PBSA), poly(ethylene succinate) (PES), and poly(ethyelene succinate adipate) (PESA); aromatic copolyesters such as poly (butylene adipate terephthalate) (PBAT), polybutylene succinate terephthalate (PBST), and poly(trimethylene terephthalate) (PTT); polycaprolactone (PCL); polyesteramides (PEA); and poly(vinyl alcohol) (PVA). In some embodiments, the compostable or biodegradable material may comprise one or more of these petroleum-derived biodegradable polymers.

The compostable or biodegradable material may also be a blend of one or more compostable or biodegradable materials derived from renewable resources and one or more compostable or biodegradable materials derived from petroleum sources. For example, the compostable or biodegradable material may comprise any one or more of polylactide (also known as polylactic acid (PLA)); polyhydroxyalkanoates (PHAs) such as poly(3-hydroxybutyrate) (PHB) and PHB copolymers; poly(butylene succinate) (PBS); thermoplastic starchs (TPS); starch blends; cellulose and cellulose esters; chitosan; protein-based polymers, aliphatic polyesters and copolyesters such as poly(butylene succinate) (PBS), poly(butylene succinate adipate) (PBSA), poly(ethylene succinate) (PES), and poly(ethyelene succinate adipate) (PESA); aromatic copolyesters such as poly (butylene adipate terephthalate) (PBAT), polybutylene succinate terephthalate (PBST), and poly(trimethylene terephthalate) (PTT); polycaprolactone (PCL); polyesteramides (PEA); and poly(vinyl alcohol) (PVA). For example, the compostable or biodegradable material may comprise a blend of one or more starch-based polymers with any one or more of the above (e.g. thermoplastic starch and polycaprolactone, thermoplastic starch and PLA, thermoplastic starch and cellulose esters, etc.).

In addition to any of the above-described materials and blends, the compostable or biodegradable material may comprise or consist of polylactic acid, crystallized polylactic acid, a polylactic aliphatic copolymer derived from one or more renewable resources (such as cornstarch, sugar cane, or the like), or a combination thereof. The compostable or biodegradable material may comprise or consist of polylactic acid, crystallized polylactic acid, a polylactic aliphatic copolymer derived from a renewable resource (such as corn starch, sugar cane, or a combination thereof), or a combination thereof, on a cellulosic paper stock. The compostable or biodegradable material may comprise or consist of polylactic acid derived from one or more renewable resources (such as cornstarch, sugarcane, or the like). The compostable or biodegradable material may comprise or consist of a compounded material that includes (i) polybutylene succinate (PBS) or polybutylene succinate-adipate (PBSA) and (ii) sunflower hull flour.

Optionally in any embodiment, the vessel 210 can contain an oxygen sensitive or moisture sensitive material, such as coffee grounds. Optionally, the vessel is closed by a closure made of plastic or metal foil. Optionally, in any embodiment, the vessel 210 may be a single-use coffee pod (capsule) having a wall 214 made from one or more compostable or biodegradable materials.

Optionally in any embodiment, the outer surface of the vessel wall 214 can be free of PECVD coatings or layers. Alternatively, an external PECVD coating set 301 can include a coating, such as a coating comprising any or all of the PECVD coatings or layers described herein.

Optionally in any embodiment, the vessel further contains an air/oxygen/moisture sensitive content, such as food, beverage or coffee grounds.

### Water Vapor Barrier Coating or Layer

Optionally in any embodiment, the water vapor bather coating or layer 300 is from 1 nm to 500 nm thick, alternatively from 1 nm to 400 nm thick, alternatively from 1 nm to 300 nm thick, alternatively from 1 nm to 200 nm thick, alternatively from 1 nm to 100 nm thick, alternatively from 1 nm to 80 nm thick, alternatively from 1 nm to 60 nm thick, alternatively from 1 nm to 50 nm thick, alternatively from 1 nm to 40 nm thick, alternatively from 1 nm to 30 nm thick, alternatively from 1 nm to 20 nm thick, alternatively from 1 nm to 10 nm thick, alternatively from 1 nm to 5 nm thick, alternatively from 10 nm to 500 nm thick, alternatively from 10 nm to 400 nm thick, alternatively from 10 nm to 300 nm thick, alternatively from 10 nm to 200 nm thick, alternatively from 10 nm to 100 nm thick, alternatively from 10 nm to 80 nm thick, alternatively from 10 nm to 60 nm thick, alternatively from 10 nm to 50 nm thick, alternatively from 10 nm to 40 nm thick, alternatively from 10 nm to 30 nm thick, alternatively from 10 nm to 20 nm thick, alternatively from 1 nm to 10 nm thick, alternatively from 1 nm to 5 nm thick, alternatively from 50 nm to 500 nm thick, alternatively from 50 nm to 400 nm thick, alternatively from 50 nm to 300 nm thick, alternatively from 50 nm to 200 nm thick, alternatively from 50 nm to 100 nm thick, alternatively from 50 nm to 80 nm thick, alternatively from 50 nm to 60 nm thick, alternatively from 100 nm to 500 nm thick, alternatively from 100 nm to 400 nm thick, alternatively from 100 nm to 300 nm thick, alternatively from 100 nm to 200 nm thick.

The coating or layer precursors comprise fluorocarbons, hydrocarbons, or hydrofluorocarbons. The fluorocarbons can be fluorinated compounds, for example a saturated or unsaturated, linear or cyclic aliphatic fluorocarbon precursor having from 1 to 10, optionally 1 to 6, optionally 2 to 6 carbon atoms and from 4 to 20 fluorine atoms per molecule. Some specific examples of suitable fluorinated compounds include fluorinated gases such as hexafluoropropylene (C3F6), octafluorocyclobutane (C4F8), tetrafluoroethylene (C2F4), or hexafluoroethane (C2F6); optionally hexafluoropropylene (C3F6) or octafluorocyclobutane (C4F8); or fluorinated liquids, such as perfluoro-2-methyl-2-pentene (C6F12) or perfluorohexane (C6F14); or any combination thereof. The hydrocarbons can be lower alkanes having from 1 to 4 carbon atoms, alkenes or alkynes having from 2 to 4 carbon atoms, for example acetylene (C2H2) or methane (CH4); optionally acetylene (C2H2). The hydrofluorocarbon can be saturated or unsaturated, having from 1 to 6 carbon atoms, at least one hydrogen atom, and at least one fluorine atom per molecule or any combination, composite, or blend of any two or more of the above materials.

For the water vapor barrier coating or layer applied using fluorocarbons or hydrofluorocarbons as the precursors, the typical coating process conditions are as follows:
Power frequency 13.56 MHz
Precursor: Hexafluoropropylene (C3F6) or Octafluorocyclobutane (C4F8)
Gas flow rate: 5-10 sccm
Carrier gas flow rate: 2-10 sccm
Base pressure 20-300 mTorr
Coating Pressure: 80-900 mTorr
Coating time: 5-30 s

For the water vapor barrier coating or layer applied using hydrocarbons as the precursors, the typical coating process conditions are as follows:
Power frequency 13.56 MHz
Precursor: Acetylene (C2H2)
Gas flow rate 1-10 sccm
Carrier gas flow rate: 2-5 sccm
Base pressure 20-300 mTorr
Coating Pressure: 80-900 mTorr
Coating time: 5-30 s

Optionally the inlet can be stationary or moving during the process.

The water vapor barrier coating or layer can be characterized using FT-IR, water contact angle, and XPS.

Generally the water vapor barrier coating or layer for any embodiment defined in this specification (unless otherwise specified in a particular instance) is a coating or layer, optionally applied by PECVD as indicated in PCT/US2019/024339.

### Tie Coating or Layer

The tie coating or layer 289 has at least two functions. One function of the tie coating or layer 289 is to improve adhesion of a barrier coating or layer 288 to a substrate, in particular a biodegradable/compostable substrate, although a tie layer can be used to improve adhesion to a glass substrate or to another coating or layer. For example, a tie coating or layer, also referred to as an adhesion coating or layer, can be applied to the substrate and the barrier layer can be applied to the adhesion layer to improve adhesion of the barrier coating or layer to the substrate.

Another function of the tie coating or layer 289 has been discovered: a tie coating or layer 289 applied under a barrier coating or layer 288 can improve the function of a pH protective coating or layer 286 applied over the barrier coating or layer 288.

The tie coating or layer 289 can be composed of, comprise, or consist essentially of SiOxCy (or the equivalent SiOxCyHz), in which x is between 0.5 and 2.4 and y is between 0.6 and 3, as measured by XPS (and z, if defined, is from about 2 to about 9 as measured by RBS, HFS, or both). Alternatively, x for the tie coating is from about 1 to about 2 as measured by XPS, y for the tie coating is from about 0.6 to about 1.5 as measured by XPS, and, if defined, z for the tie coating is from about 2 to about 5 as measured by RBS, HFS, or both

Alternatively, the atomic ratio can be expressed as the formula SiwOxCy, The atomic ratios of Si, O, and C in the tie coating or layer 289 are, as several options:

Si 100: O 50-150: C 90-200 (i.e. w=1, x=0.5 to 1.5, y=0.9 to 2);

Si 100: O 70-130: C 90-200 (i.e. w=1, x=0.7 to 1.3, y=0.9 to 2)

Si 100: O 80-120: C 90-150 (i.e. w=1, x=0.8 to 1.2, y=0.9 to 1.5)

Si 100: O 90-120: C 90-140 (i.e. w=1, x=0.9 to 1.2, y=0.9 to 1.4), or

Si 100: O 92-107: C 116-133 (i.e. w=1, x=0.92 to 1.07, y=1.16 to 1.33)

The atomic ratio can be determined by XPS. Taking into account the H atoms, which are not measured by XPS, the tie coating or layer 289 may thus in one aspect have the formula SiwOxCyHz (or its equivalent SiOxCy), for example where w is 1, x is from about 0.5 to about 2.4, y is from about 0.6 to about 3, and z (if defined) is from about 2 to about 9. Typically, tie coating or layer 289 would hence contain 36% to 41% carbon normalized to 100% carbon plus oxygen plus silicon.

Optionally, the tie coating or layer can be similar or identical in composition with the pH protective coating or layer 286 described elsewhere in this specification, although this is not a requirement.

The tie coating or layer 289 is contemplated in any embodiment generally to be from 5 nm to 100 nm thick, preferably from 5 to 20 nm thick, particularly if applied by chemical vapor deposition. These thicknesses are not critical. Commonly but not necessarily, the tie coating or layer 289 will be relatively thin, since its function is to change the surface properties of the substrate.

### Barrier Layer

A bather coating or layer 288 optionally can be deposited by plasma enhanced chemical vapor deposition (PECVD) or other chemical vapor deposition processes on the vessel of a pharmaceutical package, in particular a compostable or biodegradable package, to prevent oxygen, carbon dioxide, or other gases from entering the vessel and/or to prevent leaching of the pharmaceutical material into or through the package wall.

The barrier coating or layer for any embodiment defined in this specification (unless otherwise specified in a particular instance) is a coating or layer, optionally applied by PECVD as indicated in U.S. Pat. No. 7,985,188, PCT/US2014/023813 or PCT/US16/47622. The bather coating or layer optionally is characterized as an “SiOx” coating or layer, and contains silicon, oxygen, and optionally other elements, in which x, the ratio of oxygen to silicon atoms, is from about 1.5 to about 2.9, alternatively about 1.5 to about 2.6, alternatively about 1.5 to about 2. These alternative definitions of x apply to any use of the term SiOx in this specification.

The barrier coating or layer 288 comprises or consists essentially of SiOx, wherein x is from 1.5 to 2.9, from 2 to 1000 nm thick, the barrier coating or layer 288 of SiOx having an interior surface facing the lumen 212 and an outer surface 222 facing the wall 214 article surface 254, the barrier coating or layer 288 being effective to reduce the ingress of atmospheric gas into the lumen 212 compared to an uncoated vessel 250. One suitable barrier composition is one where x is 2.3, for example. For example, the barrier coating or layer such as 288 of any embodiment can be applied at a thickness of at least 2 nm, or at least 4 nm, or at least 7 nm, or at least 10 nm, or at least 20 nm, or at least 30 nm, or at least 40 nm, or at least 50 nm, or at least 100 nm, or at least 150 nm, or at least 200 nm, or at least 300 nm, or at least 400 nm, or at least 500 nm, or at least 600 nm, or at least 700 nm, or at least 800 nm, or at least 900 nm. The barrier coating or layer can be up to 1000 nm, or at most 900 nm, or at most 800 nm, or at most 700 nm, or at most 600 nm, or at most 500 nm, or at most 400 nm, or at most 300 nm, or at most 200 nm, or at most 100 nm, or at most 90 nm, or at most 80 nm, or at most 70 nm, or at most 60 nm, or at most 50 nm, or at most 40 nm, or at most 30 nm, or at most 20 nm, or at most 10 nm, or at most 5 nm thick. Ranges of 20-200 nm, optionally 20-30 nm, are contemplated. Specific thickness ranges composed of any one of the minimum thicknesses expressed above, plus any equal or greater one of the maximum thicknesses expressed above, are expressly contemplated.

The thickness of the SiOx or other barrier coating or layer can be measured, for example, by transmission electron microscopy (TEM), and its composition can be measured by X-ray photoelectron spectroscopy (XPS). The primer coating or layer described herein can be applied to a variety of pharmaceutical packages or other vessels made from plastic or glass, for example to plastic tubes, vials, and syringes.

A barrier coating or layer 288 of SiOx, in which x is between 1.5 and 2.9, is applied by plasma enhanced chemical vapor deposition (PECVD) directly or indirectly to the compostable or biodegradable wall 214 (for example a tie coating or layer 289 can be interposed between them) so that in the filled package or other vessel 210 the barrier coating or layer 288 is located between the inner or interior surface of the compostable or biodegradable wall 214 and the fluid, powder, or other product contained in the lumen.

The barrier coating or layer 288 of SiOx is supported by the compostable or biodegradable wall 214. The barrier coating or layer 288 described elsewhere in this specification, or in U.S. Pat. No. 7,985,188, PCT/US2014/023813, or PCT/US16/47622, can be used in any embodiment.

Certain barrier coatings or layers 288 such as SiOx as defined here have been found to have the characteristic of being subject to being measurably diminished in barrier improvement factor in less than six months as a result of attack by certain relatively high pH contents of the coated vessel as described elsewhere in this specification, particularly where the barrier coating or layer directly contacts the contents. This issue can be addressed using a pH protective coating or layer as discussed in this specification.

The barrier coating or layer 288 of SiOx also can function as a primer coating or layer, as discussed elsewhere in this specification.

### pH Protective Coating or Layer

The inventors have found that a barrier coating or layer of SiOx is eroded or dissolved by some fluids, for example aqueous compositions having a pH above about 5. Since coatings or layers applied by chemical vapor deposition can be very thin—tens to hundreds of nanometers thick—even a relatively slow rate of erosion can remove or reduce the effectiveness of the bather layer in less time than the desired shelf life of a product package. This is particularly a problem for fluid pharmaceutical compositions, since many of them have a pH of roughly 7, or more broadly in the range of 5 to 9, similar to the pH of blood and other human or animal fluids. The higher the pH of the pharmaceutical preparation, the more quickly it erodes or dissolves the SiOx coating or layer. Optionally, this problem can be addressed by protecting the barrier coating or layer 288, or other pH sensitive material, with a pH protective coating or layer 286.

Optionally, the pH protective coating or layer 286 can be composed of, comprise, or consist essentially of SiwOxCyHz (or its equivalent SiOxCy) or SiwNxCyHz (or its equivalent Si(NH)xCy), each as defined previously. The atomic ratio of Si:O:C or Si:N:C can be determined by XPS (X-ray photoelectron spectroscopy). Taking into account the H atoms, the pH protective coating or layer may thus in one aspect have the formula SiwOxCyHz, or its equivalent SiOxCy, for example where w is 1, x is from about 0.5 to about 2.4, y is from about to about 3, and z (if defined) is from about 2 to about 9.

Typically, expressed as the formula SiwOxCy, the atomic ratios of Si, O, and C are, as several options:
Si 100: O 50-150: C 90-200 (i.e. w=1, x=0.5 to 1.5, y=0.9 to 2);
Si 100: O 70-130: C 90-200 (i.e. w=1, x=0.7 to 1.3, y=0.9 to 2);
Si 100: O 80-120: C 90-150 (i.e. w=1, x=0.8 to 1.2, y=0.9 to 1.5);
Si 100: O 90-120: C 90-140 (i.e. w=1, x=0.9 to 1.2, y=0.9 to 1.4);
Si 100: O 92-107: C 116-133 (i.e. w=1, x=0.92 to 1.07, y=1.16 to 1.33);
   or
Si 100: O 80-130: C 90-150.

Alternatively, the pH protective coating or layer can have atomic concentrations normalized to 100% carbon, oxygen, and silicon, as determined by X-ray photoelectron spectroscopy (XPS) of less than 50% carbon and more than 25% silicon. Alternatively, the atomic concentrations are from 25 to 45% carbon, 25 to 65% silicon, and 10 to 35% oxygen.

Alternatively, the atomic concentrations are from 30 to 40% carbon, 32 to 52% silicon, and 20 to 27% oxygen. Alternatively, the atomic concentrations are from 33 to 37% carbon, 37 to 47% silicon, and 22 to 26% oxygen.

The thickness of the pH protective coating or layer can be, for example: from 10 nm to 1000 nm; alternatively from 10 nm to 1000 nm; alternatively from 10 nm to 900 nm; alternatively from 10 nm to 800 nm; alternatively from 10 nm to 700 nm; alternatively from 10 nm to 600 nm; alternatively from 10 nm to 500 nm; alternatively from 10 nm to 400 nm; alternatively from 10 nm to 300 nm; alternatively from 10 nm to 200 nm; alternatively from 10 nm to 100 nm; alternatively from 10 nm to 50 nm; alternatively from 20 nm to 1000 nm; alternatively from 50 nm to 1000 nm; alternatively from 10 nm to 1000 nm; alternatively from 50 nm to 800 nm; alternatively from 100 nm to 700 nm; alternatively from 300 to 600 nm.

Optionally, the atomic concentration of carbon in the protective layer, normalized to 100% of carbon, oxygen, and silicon, as determined by X-ray photoelectron spectroscopy (XPS), can be greater than the atomic concentration of carbon in the atomic formula for the organosilicon precursor. For example, embodiments are contemplated in which the atomic concentration of carbon increases by from 1 to 80 atomic percent, alternatively from 10 to 70 atomic percent, alternatively from 20 to 60 atomic percent, alternatively from 30 to 50 atomic percent, alternatively from 35 to 45 atomic percent, alternatively from 37 to 41 atomic percent.

Optionally, the atomic ratio of carbon to oxygen in the pH protective coating or layer can be increased in comparison to the organosilicon precursor, and/or the atomic ratio of oxygen to silicon can be decreased in comparison to the organosilicon precursor.

Optionally, the pH protective coating or layer can have an atomic concentration of silicon, normalized to 100% of carbon, oxygen, and silicon, as determined by X-ray photoelectron spectroscopy (XPS), less than the atomic concentration of silicon in the atomic formula for the feed gas. For example, embodiments are contemplated in which the atomic concentration of silicon decreases by from 1 to 80 atomic percent, alternatively by from 10 to 70 atomic percent, alternatively by from 20 to 60 atomic percent, alternatively by from 30 to 55 atomic percent, alternatively by from 40 to 50 atomic percent, alternatively by from 42 to 46 atomic percent.

As another option, a pH protective coating or layer is contemplated in any embodiment that can be characterized by a sum formula wherein the atomic ratio C:O can be increased and/or the atomic ratio Si:O can be decreased in comparison to the sum formula of the organosilicon precursor.

The pH protective coating or layer 286 commonly is located between the barrier coating or layer 288 and the fluid in the finished article. The pH protective coating or layer 286 is supported by the compostable or biodegradable wall 214.

The pH protective coating or layer 286 optionally is effective to keep the barrier coating or layer 288 at least substantially undissolved as a result of attack by the fluid 218 for a period of at least six months.

The pH protective coating or layer can have a density between 1.25 and 1.65 g/cm3, alternatively between 1.35 and 1.55 g/cm3, alternatively between 1.4 and 1.5 g/cm3, alternatively between 1.4 and 1.5 g/cm3, alternatively between 1.44 and 1.48 g/cm3, as determined by X-ray reflectivity (XRR). Optionally, the organosilicon compound can be octamethylcyclotetrasiloxane and the pH protective coating or layer can have a density which can be higher than the density of a pH protective coating or layer made from HMDSO as the organosilicon compound under the same PECVD reaction conditions.

The interior surface of the pH protective optionally can have a contact angle (with distilled water) of from 90° to 110°, optionally from 80° to 120°, optionally from 70° to 130°, as measured by Goniometer Angle measurement of a water droplet on the pH protective surface, per ASTM D7334—08 “Standard Practice for Surface Wettability of Coatings, Substrates and Pigments by Advancing Contact Angle Measurement.”

The passivation layer or pH protective coating or layer 286 optionally shows an O-Parameter measured with attenuated total reflection (ATR) of less than 0.4, measured as:

$$O \text{-} Parameter = \frac{Intensity at 1253 cm \text{-} 1}{Maximum i ntensity in the range 1000 to 1100 cm \text{-1}} .$$

The O-Parameter is defined in U.S. Pat. No. 8,067,070, which claims an O-parameter value of most broadly from 0.4 to 0.9. It can be measured from physical analysis of an FTIR amplitude versus wave number plot to find the numerator and denominator of the above expression, as shown and explained elsewhere. The O-Parameter can also be measured from digital wave number versus absorbance data.

U.S. Pat. No. 8,067,070 asserts that the claimed O-parameter range provides a superior pH protective coating or layer, relying on experiments only with HMDSO and HMDSN, which are both non-cyclic siloxanes. Surprisingly, it has been found by the present inventors that if the PECVD precursor is a cyclic siloxane, for example OMCTS, O-parameters outside the ranges claimed in U.S. Pat. No. 8,067,070, using OMCTS, provide even better results than are obtained in U.S. Pat. No. 8,067,070 with HMDSO.

Alternatively, in the embodiment, the O-parameter has a value of from 0.1 to 0.39, or from 0.15 to 0.37, or from 0.17 to 0.35.

Even another aspect of the invention is a composite material as just described, wherein the passivation layer shows an N-Parameter measured with attenuated total reflection (ATR) of less than 0.7, measured as:

$$N \text{-} Parameter = \frac{Intensity at 840 cm \text{-1}}{Intensity at 799 cm \text{-1}} .$$

The N-Parameter is also described in U.S. Pat. No. 8,067,070, and is measured analogously to the O-Parameter except that intensities at two specific wave numbers are used—neither of these wave numbers is a range. U.S. Pat. No. 8,067,070 claims a passivation layer with an N-Parameter of 0.7 to 1.6. Again, the present inventors have made better coatings employing a pH protective coating or layer 286 having an N-Parameter lower than 0.7, as described above. Alternatively, the N-parameter has a value of at least 0.3, or from 0.4 to 0.6, or at least 0.53.

The rate of erosion, dissolution, or leaching (different names for related concepts) of the pH protective coating or layer 286, if directly contacted by the fluid 218, is less than the rate of erosion of the barrier coating or layer 288, if directly contacted by the fluid 218.

The thickness of the pH protective coating or layer is contemplated in any embodiment to be from 50-500 nm, with a preferred range of 100-200 nm.

The pH protective coating or layer 286 is effective to isolate the fluid 218 from the barrier coating or layer 288, at least for sufficient time to allow the barrier coating or layer to act as a barrier during the shelf life of the pharmaceutical or food package or other vessel 210.

The inventors have further found that certain pH protective coatings or layers of SiOxCy or Si(NH)xCy formed from polysiloxane precursors, which pH protective coatings or layers have a substantial organic component, do not erode quickly when exposed to fluids, and in fact erode or dissolve more slowly when the fluids have higher pHs within the range of 5 to 9. For example, at pH 8, the dissolution rate of a pH protective coating or layer made from the precursor octamethylcyclotetrasiloxane, or OMCTS, is quite slow. These pH protective coatings or layers of SiOxCy or Si(NH)xCy can therefore be used to cover a barrier layer of SiOx, retaining the benefits of the barrier layer by protecting it from the fluid, powder, or other product in the vessel. The protective layer is applied over at least a portion of the SiOx layer to protect the SiOx layer from contents stored in a vessel, where the contents otherwise would be in contact with the SiOx layer.

SiOxCy or Si(NH)xCy coatings or layers also can be deposited from linear siloxane or linear silazane precursors, for example hexamethyldisiloxane (HMDSO) or tetramethyldisiloxane (TMDSO).

Optionally an FTIR absorbance spectrum of the pH protective coating or layer 286 of any embodiment has a ratio greater than 0.75 between the maximum amplitude of the Si—O—Si symmetrical stretch peak normally located between about 1000 and 1040 cm-1, and the maximum amplitude of the Si—O—Si assymmetric stretch peak normally located between about 1060 and about 1100 cm-1. Alternatively, in any embodiment, this ratio can be at least 0.8, or at least 0.9, or at least 1.0, or at least 1.1, or at least 1.2. Alternatively, in any embodiment, this ratio can be at most 1.7, or at most 1.6, or at most 1.5, or at most 1.4, or at most 1.3. Any minimum ratio stated here can be combined with any maximum ratio stated here, as an alternative embodiment.

Optionally, in any embodiment the pH protective coating or layer 286, in the absence of a liquid content in the vessel, has a non-oily appearance. This appearance has been observed in some instances to distinguish an effective pH protective coating or layer from a lubricity layer, which in some instances has been observed to have an oily (i.e. shiny) appearance.

Optionally, for the pH protective coating or layer 286 in any embodiment the total silicon content of the pH protective coating or layer and barrier coating or layer, upon dissolution into a test composition with a pH of 8 from the vessel, is less than 66 ppm, or less than 60 ppm, or less than 50 ppm, or less than 40 ppm, or less than 30 ppm, or less than 20 ppm.

In some embodiments, the vessel containing the PECVD coating set is a single-use coffee pod and the PECVD coating set is on the interior surface of the pod wall. In these embodiments, the pH protective coating or layer 286 provides protection of the barrier layer during the coffee brewing process. During the coffee brewing process, hot water and steam are introduced into the lumen of the coffee pod, where they are mixed with coffee grounds contained within the vessel. The steam and hot liquid (coffee typically has a pH between 4.6 and 6, and more typically a PH of about 5) produced during the brewing process may be capable of eroding and/or dissolving the SiOx barrier layer. Embodiments of the pH protective layer described herein have been found to be more robust than the SiOx barrier layer, offering slower erosion when exposed to fluids, and in particular fluids having pHs similar to that of the liquid content of the coffee pod during the brewing process.

Because the brewing process is typically performed within a relatively short period of time (particularly compared to a pre-filled syringe or vial containing a formulated drug solution), it is contemplated that the pH protective coating or layer may optionally be provided with a relatively low thickness while still being suitable to achieving the desired result, i.e. preventing erosion and/or dissolution of the barrier layer. For instance, the pH protective coating or layer may optionally be less than 100 nm, alternatively less than 75 nm, alternatively less than 50 nm in thickness. For example, the pH protective coating or layer may have a thickness between about 5 nm and about 100 nm, alternatively between about 5 nm and about 75 nm, alternatively between about 5 nm and about 50 nm.

### Sample Coating Protocol

Optionally the coating process is carried out in a chamber 9 as shown in FIG. 6 with the coated surface facing the fluid inlet located in the middle. Using a chamber 9 such as that shown in FIG. 6, multiple vessels 32, e.g. coffee pods, may be coated at the same time.

FIG. 6 is a schematic generic view of the trilayer plasma coating apparatus. As illustrated, the pod has its interior surface 30 facing the inlet.

Plasma gas from a fluid source 12 capable of supporting the generation of plasma in the plasma zone 15 having a boundary 20 (plasma is defined here as a visible glow discharge) is introduced via a fluid inlet 13 to a plasma zone 15, and plasma energy from a plasma energy source 18 is provided to the plasma zone 15 to generate plasma having a boundary 20 in the plasma zone 15.

Optionally in any embodiment, the tie or adhesion coating or layer (if present), the barrier coating or layer, the pH protective layer (if present), and/or the water vapor barrier coating (if present) may be applied in the same apparatus. This may optionally be performed without breaking vacuum between two or more coating steps, for example between the application of the adhesion coating or layer and the barrier coating or layer, between the barrier coating or layer and the pH protective coating or layer, or between the pH protective coating or layer and the water vapor barrier coating or layer.

During the process, a partial vacuum may be drawn in the PECVD chamber in which a plurality of the vessels, such as coffee pods, are provided. While maintaining the partial vacuum unbroken in the lumen, a tie coating or layer of SiOxCy may be applied by a tie PECVD coating set process. This process is carried out by applying sufficient power to generate plasma while feeding a gas suitable for forming the coating or layer. The gas feed includes a linear siloxane precursor, optionally oxygen, and optionally an inert gas diluent. The values of x and y are as determined by X-ray photoelectron spectroscopy (XPS). Then, optionally while maintaining the partial vacuum unbroken in the lumen, the plasma may be extinguished. A tie coating or layer of SiOxCy, for which x is from about 0.5 to about 2.4 and y is from about 0.6 to about 3, is produced on the inside surface as a result.

Later during the process, optionally while maintaining the partial vacuum unbroken in the chamber, a barrier coating or layer is applied by a barrier PECVD coating set process. The barrier PECVD coating set process is carried out by applying sufficient power to generate plasma while feeding a gas. The gas feed includes a linear siloxane precursor and oxygen. A barrier coating or layer of SiOx, wherein x is from 1.5 to 2.9 as determined by XPS is produced between the tie coating or layer and the lumen as a result. Then, optionally while maintaining the partial vacuum unbroken in the lumen, the plasma may be extinguished.

Later, as a further option, a pH protective coating or layer of SiOxCy can be applied. In this formula as well, x is from about 0.5 to about 2.4 and y is from about 0.6 to about 3, each as determined by XPS. The pH protective coating or layer is optionally applied between the barrier coating or layer and the lumen, by a pH protective PECVD coating set process. This process includes applying sufficient power to generate plasma while feeding a gas including a linear siloxane precursor, optionally oxygen, and optionally an inert gas diluent.

Later during the process, optionally while maintaining the partial vacuum unbroken, a water vapor barrier coating or layer may be applied by a water vapor barrier coating or layer PECVD process. The water vapor barrier PECVD coating set process is carried out by applying sufficient power to generate plasma while feeding a gas. The gas feed may include one or more fluorocarbon, hydrofluorocarbon, and/or hydrocarbon precursors. A water vapor barrier coating or layer may be produced on top of the pH protective coating or layer as a result.

Surprisingly, as a result of this processing, the coated vessel 210 made by a process in which the partial vacuum is maintained unbroken has a lower gas permeation rate constant into the lumen than a corresponding vessel 210 made by the same process except breaking the partial vacuum in the lumen between applying the tie coating or layer and applying the barrier coating or layer.

Surprisingly, as a result of this processing, the coated vessel 210 made by this process has a lower gas permeation rate constant into the lumen than a corresponding vessel 210 made by the same process except breaking the partial vacuum in the lumen between applying the tie coating or layer and applying the barrier coating or layer.

Alternatively, the coated vessel made by this process including the optional steps has a lower gas permeation rate constant into the lumen than a corresponding vessel made by the same process except breaking the partial vacuum in the lumen between applying the tie coating or layer and applying the barrier coating or layer, and also breaking the partial vacuum in the lumen between applying the barrier coating or layer and the pH protective coating or layer.

Optionally the trilayer coating as described in this embodiment of the invention is applied by adjusting the flows of a single organosilicon monomer (e.g. HMDSO) and oxygen and also varying the PECVD generating power between each layer (optionally without breaking vacuum between any two layers).

In some embodiments, a vessel having a wall made of a compostable or biodegradable material is placed on a vessel holder within a chamber and a vacuum is pulled within the chamber. After pulling vacuum, the gas feed of precursor, oxygen, and argon is introduced, then at the end of the “plasma delay,” continuous (i.e. not pulsed) RF power is turned on to form the tie coating or layer. Then power is turned off, gas flows are adjusted, and after the plasma delay, power is turned on for the second layer—an SiOx barrier coating or layer. This is then repeated for a third layer before the gases are cut off, the vacuum is broken, and the vessel is removed from the vessel holder. The layers are put down in the order of Tie layer, then Barrier layer, then pH Protective layer.

Optionally in any embodiment, the PECVD process for applying the tie coating or layer, the barrier coating or layer, or the pH protective coating or layer, or the water vapor barrier coating or layer, or any combination of two or more of these, is carried out by applying pulsed power (alternatively the same concept is referred to in this specification as “energy”) to generate plasma within the lumen.

Alternatively, the tie PECVD coating set process, or the barrier PECVD coating set process, or the pH protective PECVD coating set process, or the water vapor barrier coating process, or any combination of two or more of these, can be carried out by applying continuous power to generate plasma within the lumen.

Optionally, a magnetic field can be applied adjacent to the vessels while applying the electromagnetic energy, optionally for the entire applying step. The magnetic field is applied under conditions effective to reduce the standard deviation of the mean thickness of the gas barrier coating or layer on the generally cylindrical inner surface. The application of a magnetic field may improve the coating uniformity. The related apparatus and methods can be found in WO2014085348A2, which is incorporated here by reference in its entirety.

Optionally, in any embodiment, the PECVD process for applying the tie coating or layer, the barrier coating or layer, or the pH protective coating or layer, or the water vapor barrier coating or layer, or any combination of two or more of these may involve changing the feed gases used to apply adjacent layers while maintaining a plasma in the chamber, thereby creating a PECVD coating set that includes a gradient between one or more adjacent layers.

### Sample Coating Parameters

Optionally in any embodiment, depending on the size of the chamber and the number of vessels being coated at the same time during a single coating process, the RF power provided to generate plasma within the chamber for applying the PECVD coating set may be, for example, from 10 W to 600 W, alternatively from 50 W to 600 W, alternatively from 100 W to 600 W, alternatively from 200 W to 600 W.

Optionally in any embodiment, one or more layers of the PECVD coating set may be applied using a pressure of, for example, from 0.5 to 3.5 Torr, alternatively from 1 to 2.5 Torr, alternatively from 1 to 2 Torr, alternatively from 1 to 1.5 Torr.

Optionally in any embodiment, the barrier coating or layer, the optional tie coating or layer, and the optional pH protective coating or layer may be applied using any of the feed gas flowrates, RF power, and/or coating times falling within the below example ranges:

| | | HMDSO | | |
|---|---|---|---|---|
| Phase | O2 (SCCM) | (SCCM) | RF (W) | Duration (s) |
| tie | 0-2 | 5-10 | 300-600 | 60-180 |
| barrier | 30-100 | 1-10 | 200-400 | 300-900 |
| protective | 0-2 | 5-10 | 300-600 | 60-180 |

### Wall Surface Treatments

In some embodiments, prior to application of the PECVD coating set, the surface of the biodegradable or compostable wall may be treated, e.g. coated, to provide a more smooth surface upon which the PECVD coating set may be applied.

Many substrates, e.g. vessel walls, made from biodegradable or compostable materials have a relatively high degree of surface roughness. Because of the thinness of the PECVD coating set, e.g. trilayer, coatings applied in accordance with embodiments of the present disclosure (on the nanometer scale, e.g. less than 500 nm), surface roughness of the substrate can have a significant deleterious effect on the provision of a consistent coating and, as a result, on the barrier properties of the resulting coating.

In order to obtain a substrate (e.g. a vessel wall) having a more consistent PECVD coating set, it may be desirable to provide a surface treatment before applying the PECVD coating set, the surface treatment being configured to provide a smoother surface onto which the PECVD coating set can be applied. The surface treatment may comprise the provision of a relatively smooth coating or layer (compared to the surface of the underlying biodegradable or compostable material) on the surface or surfaces upon which the PECVD coating set is subsequently applied. Any material that can be applied to the substrate, e.g. the vessel wall, to create a coated substrate with a surface having a roughness that is less than the surface roughness of the substrate, itself, may be used for the surface coating.

Examples of suitable materials include: lacquers, i.e. shellac, and in particular food-grade lacquers depending on the intended use of the substrate (e.g. vessel) being coated, and lacquer alternatives, such as Zein (a vegan-friendly alternative to shellac made from a protein found in maize). In some embodiments, the material or materials used for the surface coating may itself/themselves be biodegradable or compostable. In other embodiments, the material or materials used for the surface coating may not be biodegradable or compostable. Optionally, in some embodiments, for instance where the vessel is a single-use coffee pod, the surface coating may be a food-grade lacquer or lacquer alternative such as Zein.

The surface coating may be applied by any known methods, including for example spraying, brushing, dipping, and the like. In many embodiments, for example where the vessel is a single-use coffee pod, it may be desirable that the surface coating be applied by a system, e.g. a spray system, that is configured for the coating of a high volume of vessels. In some embodiments for instance, a plurality of vessels, optionally single-use coffee pods, may be coated with a surface coating by a plasma or electrostatic spray coating process and system.

The thickness of the surface coating may be selected based on a number of factors. First, the degree of surface roughness of the underlying biodegradable or compostable substrate will largely determine how much surface coating is required to produce a surface having a desirable smoothness. For instance, a surface having larger peaks and valleys will generally require a thicker coating to be applied than a surface having relatively smaller peaks and valleys. In some embodiments, such as where the material used for the surface coating is not biodegradable or compostable, it may also be important that the amount (e.g. weight) of the applied surface coating does not exceed that which, when the combination of the surface coating and the PECVD coating set is viewed as a proportion of the wall of the fully coated vessel, would place the surface-coated vessel wall outside of the relevant standards to be considered biodegradable or compostable. In other words, the thickness of the surface coating may also be controlled by factors such as the thickness and weight of the vessel wall and, to a lesser degree, the thickness of the PECVD coating set that is subsequently applied.

Optionally, in some embodiments the surface coating may have a thickness less than 20 μm, alternatively less than 15 μm, alternatively less than 10 μm, alternatively less than 5 μm. For instance, in some embodiments, the surface coating may have a thickness between about 1 μm and 12 μm, alternatively between about 1 μm and about 10 μm, alternatively between about 1 μm and about 8 μm, alternatively between about 1 μm and about 6 μm, alternatively between about 1 μm and about 5 μm, alternatively between about 1 μm and about 4 μm, alternatively between about 1 μm and about 3 μm.

In some embodiments, the surface coating may also act as a water vapor barrier layer and/or as a barrier against leachables.

### Barrier Properties

Optionally, the vessel provided with a PECVD coating set of an embodiment disclosed herein has a lower oxygen transmission rate (OTR) than an otherwise identical vessel without the PECVD coating set; optionally, the PECVD coating set is a trilayer coating; optionally a wall surface treatment is also applied under the PECVD coating set; optionally the vessel is a single-use coffee pod.

Optionally, the vessel with a wall surface treatment applied under the PECVD coating set has a lower OTR than an otherwise identical vessel without a wall surface treatment applied under PECVD coating set.

Optionally, the vessel provided with a PECVD coating set of an embodiment disclosed herein has a lower water vapor transmission rate (WVTR) than an otherwise identical vessel without the PECVD coating set; optionally, the PECVD coating set comprises a water vapour barrier layer or coating; optionally the PECVD coating set comprises a trilayer coating; optionally a wall surface treatment is also applied under the PECVD coating set; optionally the vessel is a single-use coffee pod.

Optionally, the vessel provided with a PECVD coating set of an embodiment disclosed herein has a lower leachable profile than an otherwise identical vessel without the PECVD coating set; optionally, the PECVD coating set is a trilayer coating; optionally a wall surface treatment is also applied under the PECVD coating set; optionally the vessel is a single-use coffee pod.

Optionally, the chemical headspace of the vessel provided with a PECVD coating set of an embodiment disclosed herein shows less change over an extended period of time than an otherwise identical vessel without the PECVD coating set; optionally, the PECVD coating set is a trilayer coating; optionally a wall surface treatment is also applied under the PECVD coating set; optionally the vessel is a single-use coffee pod; optionally the chemical profile is determined by headspace analysis; optionally the headspace analysis is performed by a GC or GLC method.

Optionally, the content of a vessel provided with a PECVD coating set of an embodiment disclosed herein is subjected to less flavor scalping than an otherwise identical vessel without the PECVD coating set; optionally, the PECVD coating set is a trilayer coating; optionally a wall surface treatment is also applied under the PECVD coating set; optionally the vessel is a single-use coffee pod; optionally the amount of flavor scalping that the content of a vessel has undergone is determined by conventional coffee industry freshness and/or taste testing methods and/or panels.

In some embodiments, the vessel may be a single-use coffee pod having a biodegradable or compostable wall. Optionally the coffee pod provided with a PECVD coating set of an embodiment disclosed herein may have a greater shelf-life than an otherwise identical coffee pod without the PECVD coating set; optionally, the PECVD coating set is a trilayer coating; optionally a wall surface treatment is also applied.

Because coffee is highly sensitive to oxygen and moisture, coffee pods often have a short shelf-life. As coffee is acted on by oxygen and/or moisture, the freshness and taste of the coffee deteriorates in a process that is sometimes referred to as staling. One of the characteristic flavors of staling is rancidity, which is created the chemical oxidation or pyrolysis of fats and related compounds. Most of the volatile compounds responsible for aroma are very susceptible to oxidation and moisture. The loss and reaction of these volatile components is a significant contributor to the rancid flavor that can be found in stale coffee.

Researchers determined that oxygen was the most important factor controlling the shelf life of coffee, and showed that reducing oxygen to 0.5% in a coffee container could increase shelf life by 20-fold. Researchers similarly found that for each 1% oxygen increase there is an increase of the rate of degradation of 10%. See Labuza TP, Cardelli C, Anderson B & Shimoni E. 2001. Physical Chemistry of Roasted and Ground Coffee: Shelf Life Improvement for Flexible Packaging. Proc. 19th ASIC. Trieste. The staling or degradation of coffee beans and ground coffee beans is routinely evaluated by trained sensory assessors, who assess both the aroma and taste of the coffee.

Optionally, in some embodiments, the coffee pod provided with a PECVD coating set of an embodiment disclosed herein, and containing a ground coffee product, may have at least a 2-fold increase in shelf-life over an otherwise identical coffee pod without the PECVD coating set, alternatively at least a 3-fold increase, alternatively at least a 4-fold increase, alternatively at least a 5-fold increase. This increase in shelf-life can be determined by evaluation of the degradation of the ground coffee contained within the coffee pods by trained sensory assessors, as is known and understood in the field.

Research has also led to the development of predictive algorithms that relate oxygen uptake and the shelf life of coffee, such as that presented by Cardelli, C. & Labuza, T. P. in “Predicting Algorithms for Oxygen Uptake and Shelf Life of Dry Foods and the Application to Coffee” (2000). Cardelli and Labuza disclose that the following algorithm (identified as algorithm 1′) for calculating an estimated shelf life Θₛ has a strong correlation with experimental data.

$${θ}_{s} = \frac{\text{?} e \text{?} + \text{?}}{\text{?} e \text{?} \cdot \text{?}} \\ \text{?} \text{indicates text missing or illegible when filed} \qquad Algorithm {1}^{′}$$

The variables and methods for determining those variables are provided by Cardelli and Labuza, the entirety of which is incorporated herein by reference.

Optionally, in some embodiments, the coffee pod provided with a PECVD coating set of an embodiment disclosed herein, and containing a ground coffee product, may have an estimated shelf life Θₛ, calculated by algorithm 1′, that is at least a 2-fold increase in shelf-life over an otherwise identical coffee pod without the PECVD coating set, alternatively at least a 3-fold increase, alternatively at least a 4-fold increase, alternatively at least a 5-fold increase.

Maintenance of Biodegradability and/or Compostability

One of the key problems solved by embodiments of the present invention is the provision of gas (e.g. oxygen) and/or water (e.g. water vapour) barrier properties to a biodegradable or compostable vessel without the barrier materials having a deleterious effect on the biodegradability or compostability of the vessel.

By embodiments of the present disclosure, one may apply one or more barrier layers having a total thickness on the nanometer scale (for example less than 500 nm thick in total) to a substrate, e.g. a vessel wall, using PECVD. That allows for the provision of barrier coatings that, relative to the substrate, e.g. vessel wall, are present in a sufficiently small proportion such that the PECVD coating set does not affect the overall biodegradability or compostability designation of the substrate, e.g. vessel wall.

In this way, where a vessel wall is made from a biodegradable material, the wall having the PECVD coating set may also be biodegradable (e.g. as defined by ASTM D 6400 or EN ISO 472:2001 or other such standards). In other words, the biodegradable nature/designation of the vessel wall may be maintained even after application of the PECVD coating set. Thus, where a vessel as a whole is made from a biodegradable material, the vessel having the PECVD coating set may also be biodegradable (e.g. as defined by ASTM D 6400 or EN ISO 472:2001 or other such standards).

Similarly, where a vessel wall is made from a compostable material, the wall having the PECVD coating set may also be compostable (e.g. as defined by ASTM D 6400 or SIO/DIS 17088 or other such standards). In other words, the compostable nature/designation of the wall may be maintained even after application of the PECVD coating set. Thus, where a vessel as a whole is made from a compostable material, the vessel having the PECVD coating set may also be compostable (e.g. as defined by ASTM D 6400 or SIO/DIS 17088 or other such standards).

This may be achieved by embodiments of the present invention because, due to the thinness of the layer or layers of the PECVD coating set, the amount of material added by the PECVD coating set may be very small.

By providing a PECVD coating set that itself amounts to less than a certain wt. % of the coated vessel wall, the barrier materials (as well as any additional materials such as may be added by the inclusion of a tie layer, a pH protective layer, or both), may fall within the classification of additives that do not affect the biodegradability or compostability of the vessel wall, such as that set forth by EN 13432. Optionally, the PECVD coating set may account for less than 1 wt. % of the coated substrate, e.g. the coated vessel wall; alternatively the PECVD coating set may account for less than 0.75 wt. % of the coated substrate, e.g. the coated vessel wall; alternatively the PECVD coating set may account for less than 0.5 wt. % of the coated substrate, e.g. the coated vessel wall; alternatively the PECVD coating set may account for less than 0.25 wt. % of the coated substrate, e.g. the coated vessel wall; alternatively the PECVD coating set may account for less than 0.1 wt. % of the coated substrate, e.g. the coated vessel wall; alternatively the PECVD coating set may account for less than 0.07 wt. % of the coated substrate, e.g. the coated vessel wall; alternatively the PECVD coating set may account for less than 0.05 wt. % of the coated substrate, e.g. the coated vessel wall. For instance, in some embodiments, particularly for example those in which the vessel wall is a single-use coffee pod, the PECVD coating set may account for between about 0.01 wt. % and about 0.1 wt. % of the vessel wall, alternatively between about 0.01 wt. % and about 0.08 wt. %, alternatively between about 0.01 wt. % and about 0.06 wt. %, alternatively between about 0.01 wt. % and about 0.04 wt. %, alternatively between about 0.01 wt. % and about 0.03 wt. %.

For instance, where the vessel wall is that of a single-use coffee pod, the weight of the PECVD coating set may optionally be less than 800 micrograms, alternatively less than 700 micrograms, alternatively less than 600 micrograms, alternatively less than 500 micrograms, alternatively less than 450 micrograms, alternatively less than 400 micrograms, alternatively less than 350 micrograms, alternatively less than 300 micrograms. For instance, the PECVD coating set may optionally be present on a wall of a single-use coffee pod in an amount between about 50 and about 700 micrograms, alternatively between about 50 and about 600 micrograms, alternatively between about 100 and about 500 micrograms, alternatively between about 200 and about 500 micrograms, alternatively between about 250 and about 500 micrograms, alternatively between about 300 and about 500 micrograms.

Optionally, where a surface treatment coating is applied prior to the PECVD coating set, that surface treatment coating may also applied in a manner, i.e. at a thickness, that preserves the biodegradable or compostable nature/designation of the vessel wall (assuming that the surface coating itself is not biodegradable or compostable). For instance, the surface treatment may be applied in an amount that accounts for less than 1.0 wt. % of the vessel wall, alternatively less than 0.9 wt. %, alternatively less than 0.8 wt. %, alternatively less than 0.7 wt. %, alternatively less than 0.6 wt. %., alternatively less than 0.5 wt. %. For instance, where the vessel wall is that of a single-use coffee pod, the weight of a surface treatment coating may optionally be less than 25 milligrams, alternatively less than 22 milligrams, alternatively less than 20 milligrams, alternatively less than 19 milligrams, alternatively less than 18 milligrams, alternatively less than 16 milligrams, alternatively less than 15 milligrams.

Moreover, in some embodiments, either only the interior surface of the vessel wall may be coated or only the exterior surface of the vessel wall may be coated, such that a non-coated surface of the vessel wall is exposed to the elements during the biodegradation or composting process.

### Example 1

This example was to evaluate the OTRs/WVTRs of a coffee pod made of sunflower seed shells coated with Shellac SSB 55 Pharma FL (C₃₀H₅₀O₁₁, “Lacquer 1”) and trilayer, a coffee pod made of sunflower seed shells coated with Lacquer 1 only, and an uncoated but otherwise identical coffee pod.

A Golden Compound biodegradable and compostable coffee pod was first coated with Lacquer 1 on its interior surface by spraying.

After the pod was completely dry, a trilayer coating was applied on top of the Lacquer 1 according to following protocol.

The pods were loaded into a five-sided fixture (see FIG. 6) with pre-drilled holes designed to seat the pods securely on each of the five vertical walls. The pods were oriented so that the inside of each was facing the inlet in a three by four configuration, or 12 pods per side (three pods horizontally by 4 pods vertically). Because this application required only the inside of each pod to have a barrier coating, the outside surface of each was masked during the coating process by placing the pod to be coated inside of another masking pod before loading the stacks of two into the fixture.

Plasma gas from a fluid source 12 capable of supporting the generation of plasma in the plasma zone 15 having a boundary 20 (plasma is defined here as a visible glow discharge) was introduced via a fluid inlet 13 to a plasma zone 15, and plasma energy from a plasma energy source 18 was provided to the plasma zone 15 to generate plasma having a boundary 20 in the plasma zone 15.

A partial vacuum was drawn in the lumen. While maintaining the partial vacuum unbroken in the lumen, the tie coating or layer 289 of SiOxCy was applied by a tie PECVD process comprising applying sufficient power to generate plasma within the lumen (here 300 W) while feeding a gas comprising a linear siloxane precursor, here HMDSO. After a designated deposition time, and while maintaining the partial vacuum unbroken in the lumen, the plasma was extinguished, which had the effect of stopping application of the tie coating or layer of SiOxCy, and the feed gas was stopped.

While still maintaining the partial vacuum unbroken in the lumen, the barrier coating or layer 288 was then applied by a barrier PECVD process comprising applying sufficient power to generate plasma within the lumen (here 200 W) while feeding a gas comprising a linear siloxane precursor, here HMDSO, and oxygen. After a designated deposition time, and while maintaining the partial vacuum unbroken in the lumen, the plasma was extinguished, which had the effect of stopping application of the barrier coating or layer, and the feed gas was stopped.

While still maintaining the partial vacuum unbroken in the lumen, the pH protective coating or layer 286 of SiOxCy was then applied by a pH protective PECVD process. The pH protective PECVD process comprised applying sufficient power (here 200 W) to generate plasma within the lumen while feeding a gas comprising a linear siloxane precursor, here HMDSO. After a designated deposition time, and while maintaining the partial vacuum unbroken in the lumen, the plasma was extinguished, which had the effect of stopping application of the pH protective coating or layer, and the feed gas was stopped.

The specific coating parameters that were used for the 13.61 mL coffee pod of this example are shown in Table 1.

TABLE 1
PECVD Trilayer Process Specific Parameters

| Parameter | Units | Tie | Barrier | Protection |
|---|---|---|---|---|
| Power | W | 300 | 200 | 300 |
| HMDSO | sccm | 10 | 2 | 10 |
| Flow | | | | |
| O2 Flow | sccm | 0 | 100 | 0 |
| Argon Flow | sccm | None | None | None |
| Ramp Time | seconds | None | None | None |
| Delay Time | seconds | 15 | 10 | 10 |
| Deposition | seconds | 180 | 1200 | 60 |
| Time | | | | |

Use of the above parameters provides a total PECVD coating set thickness of about 500 nm or less. Application of the lacquer coating as described above resulted in a coating having a thickness of about 12 μm.

After the coating was completed, the coated pod and the uncoated pod were both tested for their OTRs and WVTRs according to the Testing Protocol below. The results are shown in Table 2.

TABLE 2

| | OTR | WVTR |
|---|---|---|
| Pod types | (cc/pod/day @ 1 bar) | (mg/pos/day) |
| uncoated | 0.058 | 26.0 |
| Lacquer 1 only | 0.033 | 25.8 |
| Lacquer 1 + trilayer | 0.003 | 25.9 |

The results demonstrate that the coffee pod coated with Lacquer 1 and trilayer provide better OTR than uncoated or Lacquer 1 only coated pod.

### Testing Protocol for Oxygen Transmission Rate (OTR)

The procedure described here is used to assess oxygen ingress for any vessel or package that is capable of being sealed.
Tools and Equipment
   Mocon OpTech Probe—optical unit that reads O₂ sensor and determines the partial pressure (mbar) inside a sealed container
   Mocon OpTech O₂ Sensors—oxygen sensitive fluorescent sensor applied to the inside of sealed container being tested
   Environmental Chamber
   Glass slides for sealing pods
   Two-part epoxy for sealing pods
   Test samples: coffee pods
Procedures
   Label directly onto container using a Sharpie permanent marker.
   Place O₂ sensor on glass slide.
   Place the test container inside glove box with low oxygen environment
   Seal the container with glass slide containing 02 using two-part epoxy.
   Allow 30 minutes or more for epoxy to cure.
   Initiate new test and calibrate Mocon OpTech Probe.
   Measure the internal partial pressure of the sealed container using Mocon OpTech Probe.
   Put the test container in an appropriate environmental chamber (25 & 60% RH).
   Remove the test sample from the environmental chamber every 12 hrs and measure internal partial pressure and then return sample to the environmental chamber.
   Repeat daily measurements for no less than seven days.
   Calculate the rate of oxygen ingress by converting the change of partial pressure (mbar) per day at 0.25 bar to cc/pod/per day at 1 bar.

### Testing Protocol for Water Vapor Transmission Rate (WVTR)

The procedure described here is used to assess moisture ingress for any vessel or package that is capable of being sealed.
Tools and Equipment
   Desiccant (or material under evaluation)
   Environmental Chamber
   Glass slides for sealing pods
   Two-part epoxy for sealing pods
   Test samples: coffee pods
   Analytical balance
   Nitrile Gloves
Procedures
   Label directly onto container using a Sharpie permanent marker.
   Place desiccant or material under evaluation into each container.
   Seal the container with glass slide and two-part epoxy.
   Weigh the containers on an analytical balance, at least a 4 decimal places, and record the weight as time 0.
   Put the weighed containers in an appropriate environmental chamber.
   Remove the containers from the environmental chamber at the times specified in the testing instructions/protocol/DB.
   Allow containers to equilibrate to room temperature for at least 10 minutes unless otherwise specified in the protocol/DB/testing instructions.
   Weigh the containers and record the weight according to the time point.
   Return the containers to the environmental chamber.
   Calculate amount of water inside the container by subtracting the container initial weight from the final weight and converting to milligrams.
   Calculate the rate of moisture ingress as the weight divided by the number of days of containment in the environmental chamber.

1. A vessel comprising a wall at least partially made of a biodegradable material as defined by ASTM D 6400 or EN ISO 472:2001, at least partially made of a compostable material as defined by ASTM D 6400 or ISO/DIS 17088, or both, having an interior surface enclosing a lumen, an exterior surface, and a PECVD coating set on the interior surface or the exterior surface or both, the PECVD coating set comprising:
optionally, a tie coating or layer comprising SiOₓC_{y}, in which x is from about 0.5 to about 2.4 as measured by X-ray photoelectron spectroscopy (XPS) and y is from about 0.6 to about 3 as measured by XPS;
a barrier coating or layer of SiOₓ, in which x is from about 1.5 to about 2.9, alternatively from about 1.5 to about 2.6, alternatively from about 1.5 to about 2.0, as measured by XPS, which, if a tie coating or layer is present, is positioned on top of the tie coating or layer;
optionally, a pH protective coating or layer of SiOₓC_{y}, in which x is from about 0.5 to about 2.4 as measured by XPS and y is from about 0.6 to about 3 as measured by XPS, positioned on top of the barrier coating or layer.

2. The vessel of claim 1, in which the wall is a biodegradable material as defined by ASTM D 6400 or EN ISO 472:2001; optionally wherein the wall having the PECVD coating set is also a biodegradable material as defined by ASTM D 6400 or EN ISO 472:2001.

3. (canceled)

4. (canceled)

5. The vessel of claim 1, in which the wall is a compostable material as defined by ASTM D 6400 or ISO/DIS 17088; optionally wherein the wall having the PECVD coating set is also a compostable material as defined by ASTM D 6400 or ISO/DIS 17088.

6. (canceled)

7. The vessel of claim 1, in which the PECVD coating set is only on the interior surface of the wall; optionally in which the PECVD coating set is only on the exterior surface of the wall; optionally in which a first instance of the PECVD coating set is on the exterior surface of the wall and a second instance of the PECVD coating set, which is the same as or different from the first instance of the PECVD coating set, is on the interior surface of the wall.

8. (canceled)

9. (canceled)

10. The vessel of claim 1, in which the PECVD coating set further comprises a water vapor barrier coating or layer applied by PECVD, optionally using a fluorocarbon precursor, a hydrocarbon precursor, a hydrofluorocarbon precursor, or any combination thereof.

11. The vessel of claim 1, in which the tie coating or layer is present, and optionally in which x for the tie coating is from about 1 to about 2 as measured by X-ray photoelectron spectroscopy (XPS) and y for the tie coating is from about 0.6 to about 1.5 as measured by XPS.

12. The vessel of claim 1, in which the tie coating or layer is applied by PECVD of a precursor feed comprising an organosilicon precursor.

13. The vessel of claim 12, in which the organosilicon precursor comprises or consists of tetramethylsilane (TetraMS), trimethylsilane (TriMS), hexamethyldisiloxane (HMDSO), octamethylcyclotetrasiloxane (OMCTS), tetramethyldisiloxane (TMDSO), or a combination thereof.

14. The vessel of claim 1, in which the tie coating or layer is on average from about 5 to about 200 nm thick, optionally from about 5 to about 100 nm thick, optionally from about 5 to about 50 nm thick, optionally from about 5 to about 20 nm thick.

15. The vessel of claim 1, in which the SiOx barrier coating or layer is on average from about 2 to about 1000 nm thick, optionally from 4 nm to 500 nm thick, optionally from 10 to 200 nm thick, optionally from 20 to 200 nm thick, optionally from 20 to 100 nm thick, optionally from 20 to 30 nm thick.

16. The vessel of claim 1, in which the pH protective coating or layer contacting the fluid composition is present, and optionally is from about 10 to about 1000 nm thick, optionally from about 10 to about 500 nm thick, optionally from about 10 to about 400 nm thick, optionally from about 10 to about 300 nm thick, optionally from about 10 to about 200 nm thick, optionally from about 10 to about 100 nm thick.

17. The vessel of claim 1, in which the pH protective coating or layer is applied by PECVD of a precursor feed comprising an organosilicon precursor.

18. The vessel of claim 17, in which the organosilicon precursor comprises or consists of hexamethyldisiloxane (HMDSO), trimethylsilane (TriMS), tetramethylsilane (TetraMS), tetramethyldisiloxane (TMDSO), octamethylcyclotetrasiloxane (OMCTS) or a combination thereof.

19. The vessel of claim 1, in which the thickness of the total PECVD coating set is less than 500 nm, optionally less than 400 nm, optionally less than 300 nm, optionally less than 200 nm, optionally less than 100 nm.

20. The vessel of claim 1, in which a surface smoothening coating or layer is applied directly on the wall under the PECVD coating set; optionally wherein the surface smoothening coating or layer comprises one or more materials selected from: lacquers and lacquer alternatives such as Zein; optionally wherein the surface coating or layer is a lacquer coating.

21. The vessel of claim 1, in which the compostable or biodegradable material is a single layer structure.

22. The vessel of claim 1, in which the compostable or biodegradable material is derived from a renewable raw material selected from a starch, such as cornstarch, potato starch, cassava starch, or tapioca; lignin; cellulose; soy protein; lactic acid; wood, such as bamboo or a wood-like fiber product made from bamboo; sunflower seed shells or husks; or a combination of any two or more of these.

23. The vessel of claim 1, in which the compostable or biodegradable material comprises comprise one or more of the following: polylactic acids (PLA)); polyhydroxyalkanoates (PHAs) such as poly(3-hydroxybutyrate) (PHB) and PHB copolymers; poly(butylene succinate) (PBS); thermoplastic starches (TPS); starch blends; cellulose or cellulose esters; chitosan; protein-based polymers, aliphatic polyesters and copolyesters such as poly(butylene succinate) (PBS), poly(butylene succinate adipate) (PBSA), poly(ethylene succinate) (PES), and poly(ethyelene succinate adipate) (PESA); aromatic copolyesters such as poly (butylene adipate terephthalate) (PB AT), polybutylene succinate terephthalate (PBST), and poly(trimethylene terephthalate) (PTT); polycaprolactone (PCL); polyesteramides (PEA); and poly(vinyl alcohol) (PVA).

24. The vessel of claim 1, in which the compostable or biodegradable material comprises or consists of any of the following:
polylactic acid, crystallized polylactic acid, a polylactic aliphatic copolymer derived from one or more renewable resources, or a combination thereof;
polylactic acid, crystallized polylactic acid, a polylactic aliphatic copolymer derived from a renewable resource, or a combination thereof, on a cellulosic paper stock; and
a compounded material that includes (i) polybutylene succinate (PBS) or polybutylene succinate-adipate (PBSA) and (ii) sunflower hull flour.

25. The vessel of claim 1, further comprising a closure closing the lumen.

26. The vessel of claim 25, in which the closure comprises plastic, metal foil, or a combination thereof.

27. The vessel of claim 1, in which the vessel is a food container, a coffee or tea cup, a single use coffee or tea pod, a vial, a tube, a bottle, a jar, a food package, a blister package, or a flexible package such as a pouch.

28. The vessel of claim 27, in which the vessel is a single use coffee or tea pod.

29. The vessel of claim 1, in which the vessel contains a filling material which is air sensitive, moisture sensitive, or both.

30. The vessel of claim 29, in which the filling material is a food, a beverage, or a beverage generating material from which a beverage can be made by contacting water, optionally at least one of coffee grounds, tea leaves, or a dehydrated beverage powder.

31. The vessel of claim 1, in which the vessel has a lower oxygen transfer rate (OTR); a lower water vapor transmission rate (WVTR); a lower leachable profile; or a combination thereof; than an otherwise identical vessel without a PECVD coating set.

32. The vessel of claim 1, in which the vessel has a lower oxygen transfer rate (OTR) than an otherwise identical vessel without a lacquer coating or layer.

33. (canceled)

34. (canceled)

35. The vessel of claim 1, in which the PECVD coatings prevent or reduce flavor scalping.

36. The vessel of claim 1, containing a filling material, having a headspace, and the headspace having a chemical profile defined by the identities and concentrations of one or more materials in the headspace, in which the chemical profile shows less change in the identities of materials, less change in the concentration of at least one material, or both, than that of an otherwise identical vessel without a PECVD coating set during an extended period of time; in which optionally the chemical profile is determined by headspace chemical analysis, in which optionally the headspace chemical analysis is performed by at least one of gas chromatography (GC) or gas liquid chromatography (GLC).

37. The vessel of claim 36, in which the extended time period of time is 6 months, 12 months, 18 months, 24 months, or 36 months.

38. (canceled)

39. The vessel of claim 1, in which the vessel is a single use coffee pod, the compostable or biodegradable material comprises or consists of a material derived from sunflower seed shells/husks, and the content is coffee grounds.

40. The vessel of claim 39, in which the PECVD coating set comprises the tie coating or layer.

41. The vessel of claim 39, in which the PECVD coating set comprises the pH protective coating or layer.

42. The vessel of claim 39, in which the PECVD coating set comprises a water vapor barrier coating or layer.

43. The vessel of claim 1, in which the PECVD coating set accounts for less than 1 wt. % of the coated vessel wall; alternatively in which the PECVD coating set accounts for less than 0.9 wt. % of the coated vessel wall; alternatively in which the PECVD coating set accounts for less than 0.8 wt. % of the coated vessel wall;
alternatively in which the PECVD coating set accounts for less than 0.7 wt. % of the coated vessel wall; alternatively in which the PECVD coating set accounts for less than 0.6 wt. % of the coated vessel wall; alternatively in which the PECVD coating set accounts for less than 0.5 wt. % of the coated vessel wall.

44. The vessel of claim 1, in which the vessel is a single-use coffee pod and the PECVD coating set weighs less than 600 micrograms, alternatively less than 500 micrograms, alternatively less than 400 micrograms.

45. The vessel of claim 1, in which the vessel is a single-use coffee pod that contains ground coffee, and wherein the single-use coffee pod has a greater shelf life than an otherwise identical coffee pod without the PECVD coating set; optionally in which the single-use coffee pod has a shelf-life that is at least a 2-fold increase over an otherwise identical coffee pod without the PECVD coating set; optionally in which the single-use coffee pod has a shelf-life that is at least a 3-fold increase over an otherwise identical coffee pod without the PECVD coating set; optionally in which the single-use coffee pod has a shelf-life that is at least a 4-fold increase over an otherwise identical coffee pod without the PECVD coating set.

46. A process for making a vessel according to claim 1.

47. A vessel processing system adapted for making a vessel according to claim 1.

48. The use of the vessel in claim 1, as a container for oxygen sensitive content.
